(19) United States
(12) Patent Application Publication
(10) Pub. No.: US 2012/0187504 A1
(43) Pub. Date: Jul. 26, 2012

(54) Semiconductor Device Having Shared Contact Hole and a Manufacturing Method Thereof

(75) Inventors: Motoshige Igarashi, Osaka (JP); Yuki Igarashi, Toyonaka-Shi (JP)

(73) Assignee: Renesas Electronics Corporation, Kawasaki-shi (JP)

(21) Appl. No.: 13/354,077

(22) Filed: Jan. 19, 2012

(30) Foreign Application Priority Data
Jan. 25, 2011 (JP) 2011-012777

(51) Int. Cl. H01L 27/105; H01L 21/336; H01L 29/78

(52) U.S. Cl. 257/390; 257/288; 438/294; 257/E27.081; 257/E29.255; 257/E21.409

(57) ABSTRACT

A semiconductor device has a high-speed circuit and a high-density circuit, each having at least two field effect transistors and two gate electrodes. In the high-speed circuit, a first gate electrode of a first field effect transistor and a second gate electrode of a second field effect transistor are separated by a first pitch. In the high-density circuit, a third gate electrode of a third field effect transistor and a fourth gate electrode of a fourth field effect transistor are separated by a second pitch. The first pitch is larger than the second pitch. Provision of a notch in the third gate electrode of the third field effect transistor in the high-density circuit, at a portion reached by a shared contact hole shared by the third gate electrode and the fourth transistor, increases the contact area between the shared contact hole and an impurity region source/drain of the fourth transistor.

### CROSS-REFERENCE TO RELATED APPLICATIONS

The disclosure of Japanese Patent Application No. 2011-12777 filed on Jan. 25, 2011 including the specification, drawings and abstract is incorporated herein by reference in its entirety.

### BACKGROUND

The present invention relates to a semiconductor device and a manufacturing technology thereof. More particularly, it relates to a semiconductor device having a shared contact reaching both of a gate electrode forming a field effect transistor and an impurity region formed in a substrate, and a technology effectively applicable to manufacturing thereof.

For example, Japanese Unexamined Patent Publication No. 2009-16448 (Patent Document 1) discloses a field effect transistor having the following structure: one sidewall of a gate electrode is covered with a sidewall; the other sidewall on the opposite side from the one sidewall is not covered with a sidewall; on the other sidewall side, the top surface and the side surface of the gate electrode, and the source/drain region are covered with a silicide layer, thereby to be electrically coupled; and the silicide layer is electrically coupled with a node contact electrode.

[Patent Document 1]
Japanese Unexamined Patent Publication No. 2009-16448

From the demand resulting from the trend toward higher integration of a semiconductor device, semiconductor elements are desirably designed as small as possible. This also applies to the shared contact. For example, in an integrated circuit in which a plurality of field effect transistors are formed in proximity to one another over a substrate such as a memory cell of a SRAM (Static Random Access Memory), the area required for the shared contact is reduced by reduction of the widths along respective gate length directions of respective gate electrodes, reduction of the distance between the gate electrodes adjacent in the gate length direction, reduction of the size in plan of the impurity region formed in the substrate, and the like.

However, reduction of the size in plan of the impurity region formed in the substrate reached by the shared contact hole results in reduction of the contact area between the shared contact hole and the impurity region. This incurs a problem of contact failure as follows: a coupling is not established between a conductive film embedded in the inside of the shared contact hole and the impurity region, resulting in no conduction; or even when a coupling is established between the conductive film embedded in the inside of the shared contact hole and the impurity region, the electric resistance increases. As a result, it is not possible to obtain desired operation characteristics of the field effect transistor. Accordingly, the manufacturing yield of the semiconductor device having a shared contact is reduced.

### SUMMARY

It is an object of the present invention to provide a technology capable of preventing the contact failure of a shared contact, and improving the manufacturing yield of a semiconductor device.

The foregoing and other objects and novel features of the present invention will be apparent from the description of this specification and the accompanying drawings.

One embodiment of the representative ones of the inventions disclosed in the present application will be described in brief as follows.

This embodiment is a semiconductor device which includes: in a first region of a main surface of a semiconductor substrate, a first field effect transistor; a second field effect transistor; a first insulation film covering the first field effect transistor and the second field effect transistor; and a first shared contact hole formed in the first insulation film, and reaching both of a first gate electrode of the first field effect transistor and an impurity region forming a source/drain region of the second field effect transistor, and which includes: in a second region of the main surface of the semiconductor substrate, a third field effect transistor; a fourth field effect transistor; a second insulation film covering the third field effect transistor and the fourth field effect transistor; a second shared contact hole formed in the second insulation film, and reaching both of a third gate electrode of the third field effect transistor and an impurity region forming a source/drain region of the fourth field effect transistor.

In the first region, the first gate electrode and a second gate electrode of the second field effect transistor are disposed in parallel with a predetermined distance interposed therebetween, the first gate electrode has a near-side sidewall and a far-side sidewall opposed to each other in plan view, and the near-side sidewall of the first gate electrode at a portion thereof reached by the first shared contact hole, and the near-side sidewall of the first gate electrode at a portion thereof located over a channel region are collinear.

In the second region, the third gate electrode and a fourth gate electrode of the fourth field effect transistor are disposed in parallel with a predetermined distance interposed therebetween, the third gate electrode has a near-side sidewall and a far-side sidewall opposed to each other in plan view, and the near-side sidewall of the third gate electrode at a portion thereof reached by the second shared contact hole is located to be displaced toward the far-side sidewall from an imaginary extension of the near-side sidewall of the third gate electrode at a portion thereof located over the channel region in plan view. In other words, the near-side sidewall of the third gate electrode at a portion thereof reached by the second shared contact hole and the near-side sidewall of the third gate electrode at a portion thereof located over the channel region are non-collinear. The first pitch between the first gate electrode and the second gate electrode in the first region is set larger than the second pitch between the third gate electrode and the fourth gate electrode in the second region.

In another aspect, the invention is directed to one or more methods of making a semiconductor device having shared contact holes.

The effects obtainable by one embodiment of representative ones of the inventions disclosed in the present application will be briefly described as follows.

It is possible to prevent contact failure of a shared contact, and to improve the manufacturing yield of a semiconductor device.

### BRIEF DESCRIPTION OF THE DRAWINGS

FIGS. 1A and 1B are views illustrating a configuration of field effect transistors using shared contacts in accordance with a first embodiment of the present invention, in which FIG. 1A is a planar layout view of field effect transistors formed in a circuit required to be increased in speed (high-speed circuit), and FIG. 1B is a planar layout view of field effect transistors formed in a circuit required to be increased in density (high-density circuit);

FIG. 2 is an equivalent circuit diagram of a memory cell of a SRAM in accordance with the first embodiment of the present invention;

FIG. 3 is a schematic plan view showing a planar layout configuration of various memory cells of the SRAM memory cells in accordance with the first embodiment of the present invention;

FIG. 4 is a schematic plan view showing a layout of bit lines stacked on FIG. 3;

FIG. 5 is a schematic plan view showing a layout of word lines stacked on FIG. 4;

FIG. 6 is a schematic cross-sectional view along line A-A of FIGS. 3 to 5;

FIG. 7 is a schematic plan view showing the vicinity of the shared contact holes in the SRAM memory cell in accordance with the first embodiment of the present invention;

FIG. 8 is a schematic plan view showing the vicinity of the shared contact holes in the SRAM memory cell in accordance with the first embodiment of the present invention;

FIG. 9 is a part cross-sectional view of a semiconductor device, for illustrating a manufacturing step of the semiconductor device in accordance with the first embodiment of the present invention;

FIG. 10 is a part cross-sectional view of the same portion as that of FIG. 9 of the semiconductor device during a manufacturing step following that of FIG. 9;

FIG. 11 is a plan view schematically showing a configuration of a photomask for use in a method for manufacturing a semiconductor device in accordance with the first embodiment of the present invention;

FIG. 12 is a plan view schematically showing a configuration of a photomask for use in the method for manufacturing a semiconductor device in accordance with the first embodiment of the present invention;

FIG. 13 is an essential part cross-sectional view of the same portion as that of FIG. 9 of the semiconductor device during a manufacturing step following that of FIG. 10;

FIG. 14 is an essential part cross-sectional view of the same portion as that of FIG. 9 of the semiconductor device during a manufacturing step following that of FIG. 13;

FIG. 15 is an essential part cross-sectional view of the same portion as that of FIG. 9 of the semiconductor device during a manufacturing step following that of FIG. 14;

FIG. 16 is an essential part cross-sectional view of the same portion as that of FIG. 9 of the semiconductor device during a manufacturing step following that of FIG. 15;

FIG. 17 is an essential part cross-sectional view of the same portion as that of FIG. 9 of the semiconductor device during a manufacturing step following that of FIG. 16;

FIG. 18 is an essential part cross-sectional view of the same portion as that of FIG. 9 of the semiconductor device during a manufacturing step following that of FIG. 17;

FIG. 19 is an essential part cross-sectional view of the same portion as that of FIG. 9 of the semiconductor device during a manufacturing step following that of FIG. 18;

FIG. 20 is a schematic cross-sectional view (a schematic cross-sectional view of load transistors) along line A-A of FIG. 5 in accordance with a second embodiment of the present invention;

FIG. 21 is a schematic cross-sectional view (a schematic cross-sectional view of a driving transistor) along line B-B of FIG. 5 in accordance with the second embodiment of the present invention;

FIG. 22 is a schematic cross-sectional view (a schematic cross-sectional view of a driving transistor and a load transistor) along line C-C′ of FIG. 5 in accordance with the second embodiment of the present invention;

FIGS. 23A and 23B are essential part cross-sectional views of a semiconductor device, for illustrating a manufacturing step of the semiconductor device in accordance with the second embodiment of the present invention;

FIGS. 24A and 24B are essential part cross-sectional views of the same portions as those of FIGS. 23A and 23B of the semiconductor device during a manufacturing step following that of FIGS. 23A and 23B;

FIGS. 25A and 25B are essential part cross-sectional views of the same portions as those of FIGS. 23A and 23B of the semiconductor device during a manufacturing step following that of FIGS. 24A and 24B;

FIGS. 26A and 26B are essential part cross-sectional views of the same portions as those of FIGS. 23A and 23B of the semiconductor device during a manufacturing step following that of FIGS. 25A and 25B;

FIGS. 27A and 27B are essential part cross-sectional views of the same portions as those of FIGS. 23A and 23B of the semiconductor device during a manufacturing step following that of FIGS. 26A and 26B;

FIGS. 28A and 28B are essential part cross-sectional views of the same portions as those of FIGS. 23A and 23B of the semiconductor device during a manufacturing step following that of FIGS. 27A and 27B;

FIGS. 29A and 29B are essential part cross-sectional views of the same portions as those of FIGS. 23A and 23B of the semiconductor device during a manufacturing step following that of FIGS. 28A and 28B;

FIGS. 30A and 30B are essential part cross-sectional views of the same portions as those of FIGS. 23A and 23B of the semiconductor device during a manufacturing step following that of FIGS. 29A and 29B;

FIGS. 31A and 31B are essential part cross-sectional views of the same portions as those of FIGS. 23A and 23B of the semiconductor device during a manufacturing step following that of FIGS. 30A and 30B; and

FIGS. 32A and 32B are essential part cross-sectional views of the same portions as those of FIGS. 23A and 23B of the semiconductor device during a manufacturing step following that of FIGS. 31A and 31.

### DETAILED DESCRIPTION

In the following embodiment, the embodiment may be described in a plurality of divided sections or embodiments for convenience, if required. However, unless otherwise specified, these are not independent of each other, but are in a relation such that one is a modified example, detailed explanation, complementary explanation, or the like of a part or the whole of the other.

Further, in the following embodiments, when a reference is made to the number of elements, and the like (including number, numerical value, quantity, range, or the like), the number of elements is not limited to the specific number, but may be greater than or less than the specific number, unless otherwise specified, and except the case where the number is apparently limited to the specific number in principle, and other cases. Further, in the following embodiments, the constitutional elements (including element steps, or the like) are not always essential, unless otherwise specified, and except the case where they are apparently considered essential in principle, and other cases. Similarly, in the following embodiments, when a reference is made to the shapes, positional relationships, or the like of the constitutional elements, or the like, it is understood that they include ones substantially analogous or similar to the shapes or the like, unless otherwise specified, unless otherwise considered apparently in principle, and except for other cases. This also applies to the foregoing numbers and ranges.

Further, in the drawings for use in the following embodiments, even a plan view may be hatched for easy view of the drawing. Still further, in the following embodiments, a MISFET (Metal Insulator Semiconductor Field Effect Transistor) representative of field effect transistors is abbreviated as a MIS. A p channel type MISFET is abbreviated as a pMIS, and an n channel type MISFET is abbreviated as an nMIS. Further, in the following embodiments, the term “wafer” herein used mainly denotes a Si (Silicon) single crystal wafer, but the term “wafer” indicates not only it but also a SOI (Silicon On Insulator) wafer, an insulation film substrate for forming an integrated circuit thereover, or the like. The shape thereof is also not limited to a circle or a nearly circle, but includes a square, a rectangle, or the like.

Further, in all the drawings for describing the following embodiments, those having the same function are given the same reference signs and numerals in principle, and a repeated description thereon is omitted. Below, the embodiments of the present invention will be described in details by reference to the accompanying drawings.

### First Embodiment

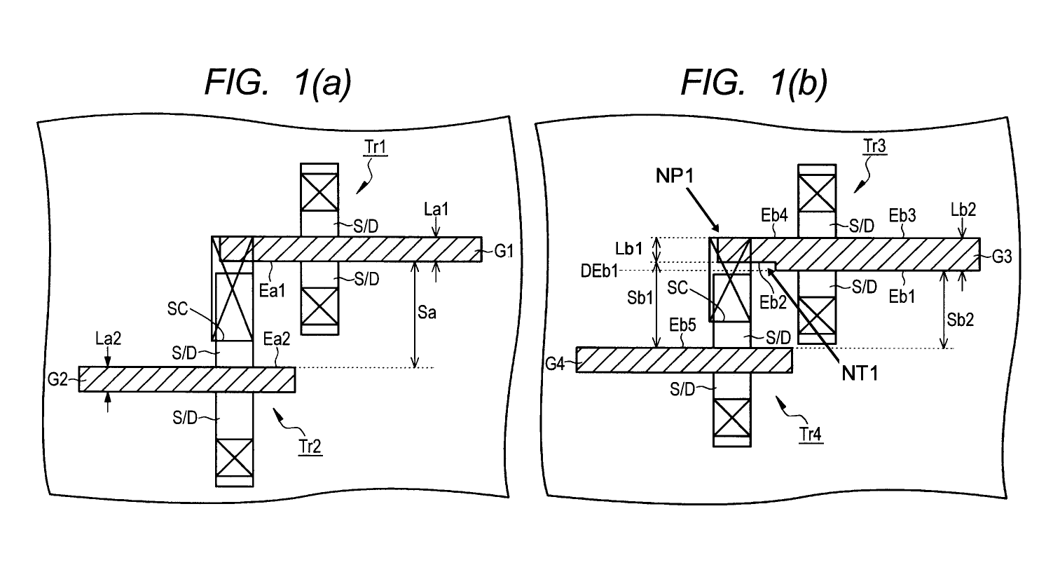

A configuration of a field effect transistor using a shared contact in accordance with a first embodiment will be described by reference to FIGS. 1A and 1B. FIG. 1A is a planar layout view of field effect transistors formed in a circuit required to be increased in speed (high-speed circuit). FIG. 1B is a planar layout view of field effect transistors formed in a circuit required to be increased in density (high-density circuit).

In a semiconductor device including a plurality of functional circuits formed over a semiconductor substrate such as a system on chip: SoC, a high-speed circuit and a high-density circuit are merged. For respective circuits, there is performed layout design of various semiconductor elements for satisfying the functions required of respective circuits.

FIG. 1A is one example of the planar layout view of field effect transistors formed in a high-speed circuit.

A field effect transistor Tr1 and a field effect transistor Tr2 formed in a main surface of a semiconductor substrate are disposed at a predetermined distance apart from each other. The width La1 along the gate length direction of a gate electrode G1 of the field effect transistor Tr1 over the channel region and over the element isolation part, and the width La2 along the gate length direction of a gate electrode G2 of the field effect transistor Tr2 over the channel region and over the element isolation part are constant, respectively. Further, the gate electrode G1 of the field effect transistor Tr1 and the gate electrode G2 of the field effect transistor Tr2 are disposed in such a manner as to extend in the gate width direction, and to be in parallel with each other. The width La1 of the gate electrode G1 and the width La2 of the gate electrode G2 may be the same. Further, the distance Sa between a sidewall Ea1 of the gate electrode G1 of the field effect transistor Tr1 and a sidewall Ea2 of the gate electrode G2 of the field effect transistor Tr2 opposing each other is constant.

Further, in order to electrically couple the gate electrode G1 of the field effect transistor Tr1 and an impurity region S/D forming the source/drain of the field effect transistor Tr2, there is formed a shared contact hole SC reaching both of a portion of the gate electrode G1 of the field effect transistor Tr1 located over the element isolation part and the impurity region S/D forming the source/drain region of the field effect transistor Tr2.

In a high-speed circuit, a current is required to flow in a large amount through the field effect transistors Tr1 and Tr2. For this reason, the widths La1 and La2 along the gate length direction of the gate electrodes G1 and G2 are desirably small. Thus, the widths La1 and La2 along the gate length direction of respective gate electrodes G1 and G2 of the field effect transistors Tr1 and Tr2 are each set at, for example, a design minimum size (e.g., 30 nm).

On the other hand, the high-speed circuit has a larger margin in layout design than that of a high-density circuit described later. For this reason, the first pitch (distance) between the gate electrode G1 of the field effect transistor Tr1 and the gate electrode G2 of the field effect transistor Tr2 can be set larger than that of the high-density circuit described later. Therefore, the contact area between the shared contact hole SC and the impurity region S/D can be set wide. This can stably provide a conduction between a conductive film embedded in the inside of the shared contact hole SC and the impurity region S/D.

Incidentally, the widths La1 and La2 along the gate length direction of respective gate electrodes G1 and G2 of the field effect transistors Tr1 and Tr2 were each set at, for example, the design minimum size (e.g., 30 nm). However, the widths La1 and La2 are each not limited to the design minimum size, and may be set larger than the design minimum size. Even when the widths La1 and La2 along the gate length direction are set larger, the threshold voltages of the field effect transistors Tr1 and Tr2 can be adjusted, and desirable operation characteristics can be obtained. However, when the widths La1 and La2 along the gate length direction are increased, variations in characteristics between elements may be caused.

FIG. 1B is one example of a planar layout view of field effect transistors formed in a high-density circuit.

As with the high-speed circuit, a field effect transistor Tr3 and a field effect transistor Tr4 formed in the main surface of the semiconductor substrate are disposed at a predetermined distance apart from each other. Further, a gate electrode G3 of the field effect transistor Tr3 and a gate electrode G4 of the field effect transistor Tr4 are disposed in such a manner as to extend in the gate width direction, and to be in parallel with each other.

Further, in order to electrically couple the gate electrode G3 of the field effect transistor Tr3 and an impurity region S/D forming the source/drain region of the field effect transistor Tr4, there is formed a shared contact hole SC reaching both of a portion of the gate electrode G3 of the field effect transistor Tr3 located over the element isolation part and the impurity region S/D forming the source/drain region of the field effect transistor Tr4.

Incidentally, in the high-density circuit, the second pitch (distance) between the gate electrode G3 of the field effect transistor Tr3 and the gate electrode G4 of the field effect transistor Tr4 is desirably set small. Further, respective widths along the gate length direction of the gate electrodes G3 and G4 of the field effect transistors Tr3 and Tr4 are set optimum according to the operation characteristics. For this reason, the widths may be each designed to be larger than the minimum design size. Accordingly, when the pitch is simply set smaller, the size in plan of the impurity region S/D forming the source/drain region decreases. This results in a reduction of the contact area between the shared contact hole SC and the impurity region S/D.

Thus, as shown in FIG. 1B, the shape in plan view of the gate electrode G3 of the field effect transistor Tr3 was set different from the shape in plan view of the gate electrode G1 of the field effect transistor Tr1 formed in the high-speed circuit. Namely, at a portion which is the end in the long side direction (gate width direction) of the gate electrode G3 located over the element isolation part, and which is reached by the shared contact hole SC, a notch NT1 is provided in the sidewall of the gate electrode G3 of the field effect transistor Tr3 opposing the gate electrode G4 of the field effect transistor Tr4. In other words, in plan view, the gate electrode G3 has non-collinear near-side sidewalls Eb1 and Eb2 on the side of gate G3 which faces field effect transistor Tr4, and collinear, far-side sidewalls Eb3 and Eb4 on the side of gate G3 facing away from field effect transistor Tr4. The non-collinear, near-side sidewalls Eb1 and Eb2 and the collinear, far-side sidewalls Eb3 and Eb4 are opposed to each other in plan view. In plan view, the near-side sidewall Eb2 of the gate electrode G3 at the portion reached by the shared contact hole SC is located to be displaced in such a manner as to retreat from an imaginary extension DEb1 of the near-side sidewall Eb1 at another portion not reached by the shared contact hole SC such as a portion in the channel region toward the far-side sidewalls Eb3 and Eb4. Thus, notched gate electrode G3 having notch NT1 has a different construction than non-notched gate electrode GE1, which is devoid of a notch.

Further, the notch-provided portion of the gate electrode G3 (which will be hereinafter described as a notched portion NP1) is not in a tapered shape. The width along the gate length direction of the notched portion NP1 has a substantially constant width Lb1.

As a result, in the region in which there is formed the shared contact hole SC reaching both of the gate electrode G3 of the field effect transistor Tr3, and the impurity region S/D forming the source/drain region of the field effect transistor Tr4, the distance Sb1 between the sidewall Eb2 at the notched portion NP1 of the gate electrode G3 of the field effect transistor Tr3 and the sidewall Eb5 of the gate electrode G4 of the field effect transistor Tr4 opposed thereto is larger than the distance Sb2 between the sidewall Eb1 at another portion of the gate electrode G3 of the field effect transistor Tr3 in which a notch is not provided and the sidewall Eb5 of the gate electrode G4 of the field effect transistor Tr4 opposed thereto. Therefore, the contact area between the shared contact hole SC and the impurity region S/D can be set large. This can provide a conduction between a conductive film embedded in the inside of the shared contact hole SC and the impurity region S/D with stability.

The width Lb1 along the gate length direction in the notched portion NP1 of the gate electrode G3 of the field effect transistor Tr3 is naturally smaller than the width Lb2 along the gate length direction in other portions of the gate electrode G3 of the field effect transistor Tr3 in which no notch is provided. However, in view of the problem of processing precision or the like, the width Lb1 of the notched portion NP1 is set equal to, or larger than the design minimum size. The width Lb2 of other portions in which no notch is provided is set 5 nm or more larger than the width Lb1 of the notched portion NP1. For example, if the width Lb1 of the notched portion NP1 is set at 30 nm, then the width Lb2 of other portions of gate electrode G3 in which no notch is provided is set at 35 to 40 nm.

Thus, in accordance with the first embodiment, in the high-speed circuit, the first pitch between the gate electrode G1 of the field effect transistor Tr1 and the gate electrode G2 of the field effect transistor Tr2 is set larger than that of the high-density circuit. This results in a large contact area between the shared contact hole SC and the impurity region S/D. This can provide conduction between a conductor film embedded in the inside of the shared contact hole SC and the impurity region S/D with stability.

On the other hand, in the high-density circuit, the second pitch between the gate electrode G3 of the field effect transistor Tr3 and the gate electrode G4 of the field effect transistor Tr4 is smaller than that of the high-speed circuit. However, in the gate electrode G3 at a portion thereof reached by the shared contact hole SC, a notch NT1 is provided. Accordingly, the contact area between the shared contact hole SC and the impurity region S/D is set large. This can provide conduction between a conductor film embedded in the inside of the shared contact hole SC and the impurity region S/D with stability.

Then, a description will be given to the case where the present invention is applied to a memory cell of a SRAM (Static Random Access Memory). The SRAM has a high utility value as a main storage device in various arithmetic units or the like because of the high-speed writing and reading performances. On the other hand, each 1-bit cell (unit cell) for storing 1-bit information requires six elements (field effect transistors), and hence the SRAM has been regarded as not being suitable for integration. However, as one of manufacturing technologies capable of implementing densification, there is adopted a shared contact capable of implementing simplification of wiring.

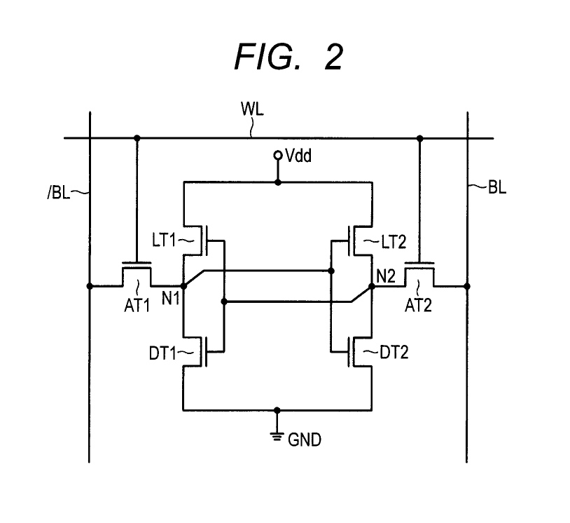

FIG. 2 is an equivalent circuit diagram of a memory cell for 1 bit (1-bit cell) of a SRAM. The SRAM is a volatile semiconductor storage device. The memory cell of the SRAM is, for example, a full CMOS (Complementary Metal Oxide Semiconductor) type memory cell.

In the SRAM, memory cells are arranged at intersections between complementary data lines (bit lines) BL and /BL and word lines WL arranged in a matrix. The memory cell includes a flip-flop circuit including a pair of inverter circuits, and two information transfer transistors AT1 and AT2. The flip-flop circuit forms two cross-coupled storage nodes N1 and N2, so that the bistable state of (High, Low) or (Low, High) is achieved. The memory cell continues to hold the bistable state so long as it is applied with a predetermined source voltage.

Each of the pair of transfer transistors AT1 and AT2 includes, for example, an n-channel type MISFET (which will be hereinafter described as an nMIS). One of the source/drain of the transfer transistor AT1 is electrically coupled with the storage node N1. The other of the source/drain is electrically coupled with the bit line /BL. Whereas, one of the source/drain of the transfer transistor AT2 is electrically coupled with the storage node N2. The other of the source/drain is electrically coupled with the bit line BL. Further, each of the transfer transistors AT1 and AT2 is electrically coupled with the word line WL. The word line WL controls the conducting and non-conducting states of the transfer transistors AT1 and AT2.

The inverter circuit includes one driving transistor DT1 (or DT2) and one load transistor LT1 (or LT2).

Each of the pair of driving transistors DT1 and DT2 includes, for example, an nMIS. Respective sources of the pair of driving transistors DT1 and DT2 are electrically coupled with the ground potential GND. Whereas, the drain of the driving transistor DT1 is electrically coupled with the storage node N1. The drain of the driving transistor DT2 is electrically coupled with the storage node N2. Further, the gate of the driving transistor DT1 is electrically coupled with the storage node N2. The gate of the driving transistor DT2 is electrically coupled with the storage node N1.

Each of a pair of load transistors LT1 and LT2 includes, for example, a p-channel type MISFET (which will be hereinafter described as a pMIS). Respective sources of the pair of load transistors LT1 and LT2 are electrically coupled with the source voltage Vdd. Whereas, the drain of the load transistor LT1 is electrically coupled with the storage node N1. The drain of the load transistor LT2 is electrically coupled with the storage node N2. Further, the gate of the load transistor LT1 is electrically coupled with the storage node N2. The gate of the load transistor LT2 is electrically coupled with the storage node N1.

When data is written into the memory cell, the word line WL is selected to render the transfer transistors AT1 and AT2 into the conducting state. Thus, the bit line pair BL and /BL are forcibly applied with a voltage according to the desirable theoretical value. As a result, the flip-flop circuit is set to either of the bistable states. Whereas, when data is read from the memory cell, the transfer transistors AT1 and AT2 are set in the conducting state, so that the potentials of the storage nodes N1 and N2 are transferred to the bit lines BL and /BL.

In the configuration of the semiconductor device in accordance with the first embodiment, the gate electrode of the load transistor LT1 and the drain region of the load transistor LT2 are electrically coupled with each other via a shared contact. The gate electrode of the load transistor LT2 and the drain region of the load transistor LT1 are electrically coupled with each other via a shared contact. Below, the configuration will be described.

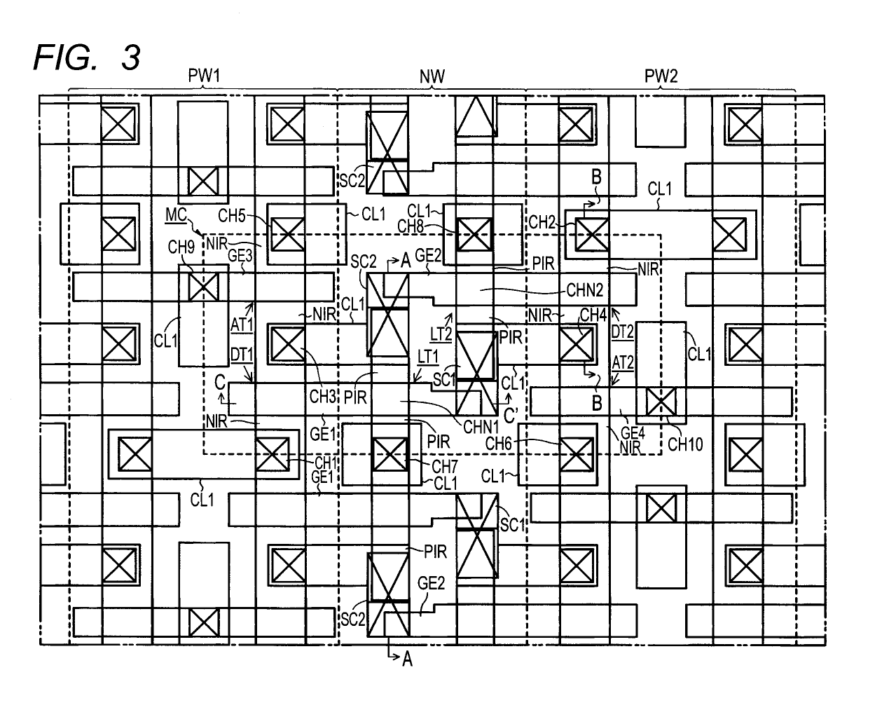

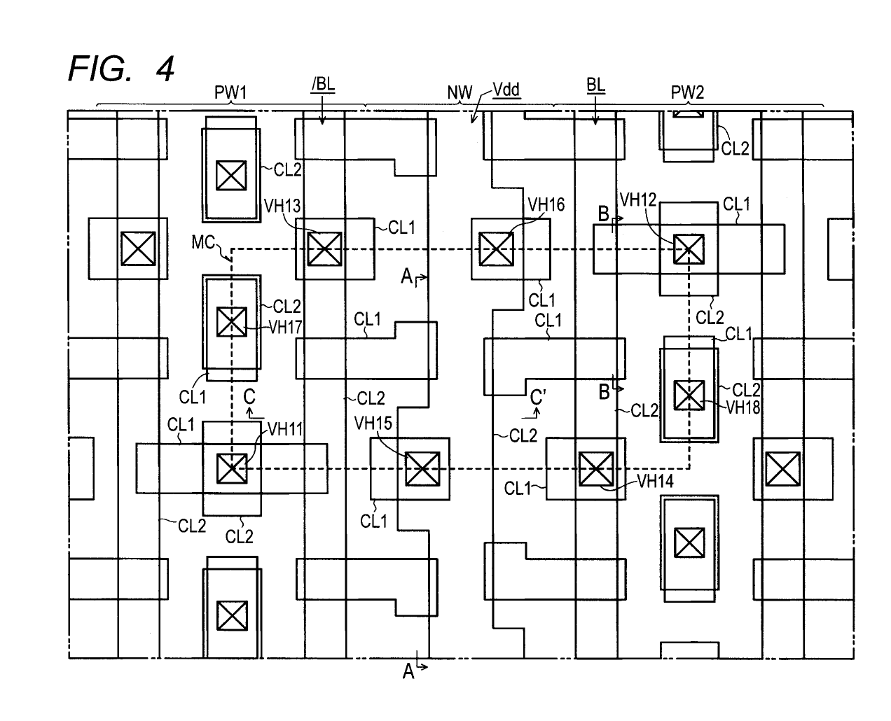

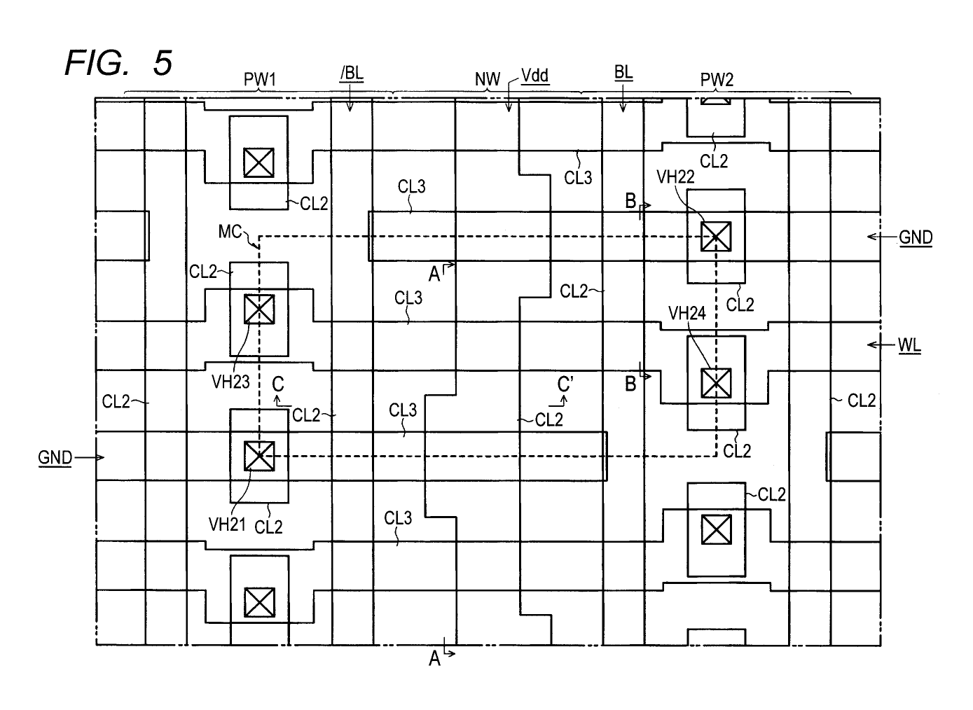

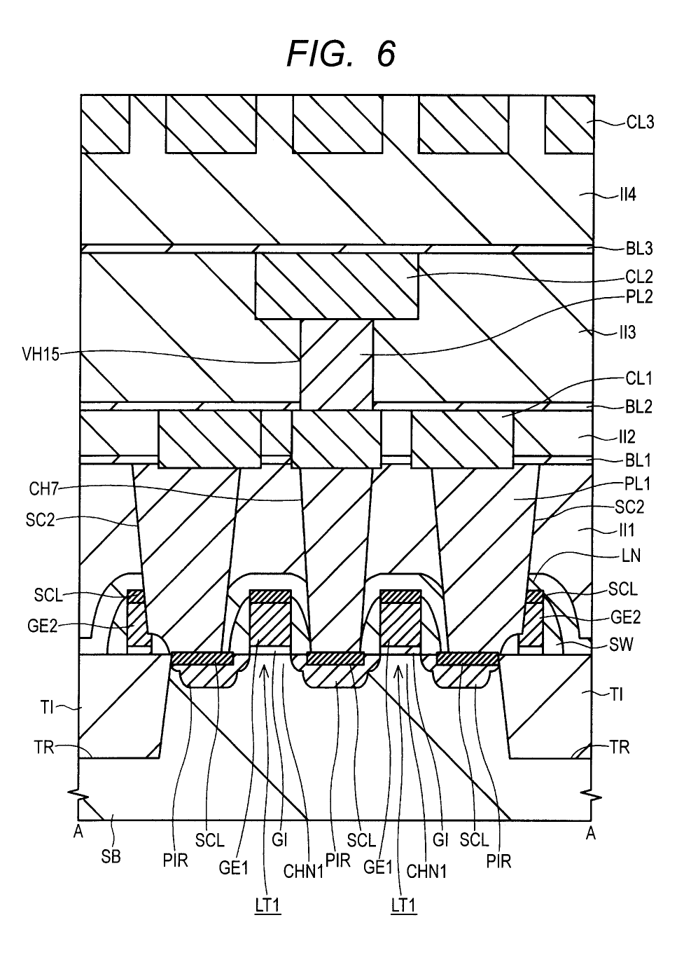

FIGS. 3 to 5 are each a schematic plan view showing the planar layout configuration of the memory cell of the SRAM in accordance with the first embodiment. FIG. 3 is a schematic plan view showing the planar layout structure of various transistors (the transfer transistors AT1 and AT2, the driving transistors DT1 and DT2, and the load transistors LT1 and LT2) forming the memory cell. FIG. 4 is a schematic plan view showing the layout of the bit lines stacked on FIG. 3. FIG. 5 is a schematic plan view showing the layout of the word lines stacked on FIG. 4. Further, FIG. 6 is a schematic cross-sectional view along line A-A of FIG. 5.

As shown in FIGS. 3 to 6, in the main surface of the semiconductor substrate SB, there is formed an element isolation part including, for example, STI (Shallow Trench Isolation). The element isolation part has a trench TR for isolation formed in the main surface of the semiconductor substrate SB, and a filling TI including silicon oxide embedded in the trench TR.

In the main surface of the semiconductor substrate SB isolated by the element isolation trench, a plurality of memory cells are formed. In one memory cell region MC (a region enclosed by a broken line in FIGS. 3 to 5), there are formed a pair of driving transistors DT1 and DT2, a pair of transfer transistors AT1 and AT2, and a pair of load transistors LT1 and LT2.

The pair of driving transistors DT1 and DT2 and the pair of transfer transistors AT1 and AT2 each include, for example, an nMIS, and are formed in p-type well regions PW1 and PW2 in the main surface of the semiconductor substrate SB. Whereas, the pair of load transistors LT1 and LT2 each include, for example, a pMIS, and are formed in an n-type well region NW in the main surface of the semiconductor substrate SB.

The driving transistor DT1 has a pair of n-type impurity regions NIR serving as a pair of source/drain regions, and a gate electrode GE1. The pair of n-type impurity regions NIR are respectively formed apart from each other in the main surface of the semiconductor substrate SB in the p-type well region PW1. The gate electrode GE1 is formed over a channel region interposed between the pair of n-type impurity regions NIR with a gate insulation film (not shown) interposed therebetween.

The driving transistor DT2 has a pair of n-type impurity regions NIR serving as a pair of source/drain regions, and a gate electrode GE2. The pair of n-type impurity regions NIR are respectively formed apart from each other in the main surface of the semiconductor substrate SB in the p-type well region PW2. The gate electrode GE2 is formed over a channel region interposed between the pair of n-type impurity regions NIR with a gate insulation film (not shown) interposed therebetween.

The transfer transistor AT1 has a pair of n-type impurity regions NIR to be a pair of source/drain regions, and a gate electrode GE3. The pair of n-type impurity regions NIR are respectively formed apart from each other in the main surface of the semiconductor substrate SB in the p-type well region PW1. The gate electrode GE3 is formed over a channel region interposed between the pair of n-type impurity regions NIR with a gate insulation film (not shown) interposed therebetween.

The transfer transistor AT2 has a pair of n-type impurity regions NIR to be a pair of source/drain regions, and a gate electrode GE4. The pair of n-type impurity regions NIR are respectively formed apart from each other in the main surface of the semiconductor substrate SB in the p-type well region PW2. The gate electrode GE4 is formed over a channel region interposed between the pair of n-type impurity regions NIR with a gate insulation film (not shown) interposed therebetween.

The load transistor LT1 has a pair of p-type impurity regions PIR to be a pair of source/drain regions, and a gate electrode GE1. The pair of p-type impurity regions PIR are respectively formed apart from each other in the main surface of the semiconductor substrate SB in the n-type well region NW. The gate electrode GE1 is formed over a channel region CHN1 interposed between the pair of p-type impurity regions PIR with a gate insulation film (not shown) interposed therebetween.

The load transistor LT2 has a pair of p-type impurity regions PIR to be a pair of source/drain regions, and a gate electrode GE2. The pair of p-type impurity regions PIR are respectively formed apart from each other in the main surface of the semiconductor substrate SB in the n-type well region NW. The gate electrode GE2 is formed over a channel region CHN2 interposed between the pair of p-type impurity regions PIR with a gate insulation film (not shown) interposed therebetween.

The drain region of the driving transistor DT1 and one of the pair of source/drain regions of the transfer transistor AT1 are formed of the same n-type impurity region NIR. Whereas, the drain region of the driving transistor DT2, and one of the pair of source/drain regions of the transfer transistor AT2 are formed of the mutually same n-type impurity region NIR.

The gate electrode GE1 of the driving transistor DT1 and the gate electrode GE1 of the load transistor LT1 are formed of the mutually same notched conductive film. Whereas, the gate electrode GE2 of the driving transistor DT2 and the gate electrode GE2 of the load transistor LT2 are formed of the mutually same notched conductive film. Meanwhile, gate electrodes GE3 and GE4 which serve transfer transistors AT1 and AT2, respectively, belong to different non-notched conductive films. As mainly shown in FIG. 6, silicide films SCL are formed in such a manner as to be in contact with respective gate electrodes, and source/drain regions of the transistors DT1, DT2, AT1, AT2, LT1, and LT2. Further, a liner nitride film LN and a first interlayer insulation film II1 are sequentially stacked and formed over the semiconductor substrate SB in such a manner as to cover respective gate electrodes, source/drain regions, and the like of the transistors DT1, DT2, AT1, AT2, LT1, and LT2. Herein, the first interlayer insulation film II1 includes, for example, silicon oxide. In the liner nitride film LN and the first interlayer insulation film II1, there are formed a plurality of contact holes CH1 to CH10 and a plurality of shared contact holes SC1 and SC2.

As mainly shown in FIG. 3, specifically, in the liner nitride film LN and the first interlayer insulation film II1, there are formed the contact holes CH1 and CH2 reaching respective source regions of the driving transistors DT1 and DT2, respectively. Whereas, in the liner nitride film LN and the first interlayer insulation film II1, there are formed the contact holes CH3 and CH4 reaching respective ones of the pairs of source/drain regions of the transfer transistors AT1 and AT2 (respective drain regions of the driving transistors DT1 and DT2), respectively. Further, in the liner nitride film LN and the first interlayer insulation film II1, there are formed the contact holes CH5 and CH6 reaching respective others of the pairs of source/drain regions of the transfer transistors AT1 and AT2, respectively. Whereas, in the liner nitride film LN and the first interlayer insulation film II1, there are formed the contact holes CH7 and CH8 reaching respective source regions of the load transistors LT1 and LT2, respectively.

Further, in the liner nitride film LN and the first interlayer insulation film II1, there is formed a shared contact hole SC1 reaching both of the gate electrode GE1 of the load transistor LT1 and the drain region of the load transistor LT2. Whereas, in the liner nitride film LN and the first interlayer insulation film II1, there is formed a shared contact hole SC2 reaching both of the gate electrode GE2 of the load transistor LT2 and the drain region of the load transistor LT1.

As mainly shown in FIG. 6, a conductive film PL1 fills each of the plurality of contact holes CH1 to CH10 and the shared contact holes SC1 and SC2. Over the first interlayer insulation film II1, an insulation film BL1 and a second interlayer insulation film II2 are sequentially stacked and formed. Herein, the insulation film BL1 includes, for example, silicon nitride, silicon carbide, silicon oxycarbide, or silicon oxynitride. The second interlayer insulation film II2 includes, for example, silicon oxide. In the insulation film BL1 and the second interlayer insulation film II2, a plurality of through holes are formed. In respective insides of the plurality of through holes, a plurality of first conductive films (first metal layers) CL1 are embedded, respectively. The plurality of first conductive films CL1 form a first conductive film pattern.

As mainly shown in FIG. 3, the conductive film CL1 electrically couples the conductive film PL1 in the shared contact hole SC1 with the conductive film PL1 in the contact hole CH4. As a result, the gate electrode GE1 of the load transistor LT1, the drain region of the load transistor LT2, the drain region of the driving transistor DT2, and one of the pair of source/drain regions of the transfer transistor AT2 are electrically coupled to one another, as indicated by the node N2 in FIG. 2.

Further, the conductive film CL1 electrically couples the conductive film PL1 in the shared contact hole SC2 and the conductive film PL1 in the contact hole CH3. As a result, the gate electrode GE2 of the load transistor LT2, the drain region of the load transistor LT1, the drain region of the driving transistor DT1, and one of the pair of source/drain regions of the transfer transistor AT1 are electrically coupled to one another, as indicated by the node N1 in FIG. 2.

Further, the conductive films PL1 in respective insides of the contact holes CH1, CH2, and CH5 to CH10 are also individually electrically coupled with the conductive film CL1.

As mainly shown in FIG. 6, over the second interlayer insulation film II2, an insulation film BL2 and a third interlayer insulation film II3 are sequentially stacked and formed. Herein, the insulation film BL2 includes, for example, silicon nitride, silicon carbide, silicon oxycarbide, or silicon oxynitride. The third interlayer insulation film II3 includes, for example, silicon oxide. In the insulation film BL2 and the third interlayer insulation film II3, there are formed a plurality of via holes VH11 to VH18 (see FIG. 4). A conductive film-embedding trench is formed in the surface of the third interlayer insulation film II3 in such a manner as to communicate with each of the plurality of via holes VH11 to VH18.

In each of the plurality of via holes VH11 to VH18, a conductive film PL2 is embedded. Further, in the plurality of conductive film-embedding trenches, a plurality of second conductive films (second metal layers) CL2 are embedded, respectively. The plurality of second conductive films CL2 form a second conductive film pattern.

As mainly shown in FIGS. 2 and 4, the conductive film CL2 electrically coupled to the other of the pair of source/drain regions of the transfer transistor AT1 via the via hole VH13 and the contact hole CH5 functions as the bit line /BL. Whereas, the conductive film CL2 electrically coupled to the other of the pair of source/drain regions of the transfer transistor AT2 via the via hole VH14 and the contact hole CH6 functions as the bit line BL. Further, the conductive film CL2 electrically coupled to the source region of the load transistor LT1 via the via hole VH15 and the contact hole CH7, and electrically coupled to the source region of the load transistor LT2 via the via hole VH16 and the contact hole CH8 functions as a source (Vdd) line. The bit lines BL and /BL and the source (Vdd) line extend in such a manner as to run in parallel with each other along the longitudinal direction in the drawing, (i.e., between top and bottom in FIG. 4).

Further, the conductive films in respective insides of the via holes VH11, VH12, VH17, and VH18 are also individually electrically coupled with the conductive films CL2, respectively.

As mainly shown in FIG. 6, over the third interlayer insulation film II3, an insulation film BL3 and a fourth interlayer insulation film II4 are sequentially stacked and formed. Herein, the insulation film BL3 includes, for example, silicon nitride, silicon carbide, silicon oxycarbide, or silicon oxynitride. The fourth interlayer insulation film II4 includes, for example, silicon oxide. In the insulation film BL3 and the fourth interlayer insulation film II4, there are formed a plurality of via holes VH21 to VH24 (FIG. 5). A conductive film-embedding trench is formed in the surface of the fourth interlayer insulation film II4 in such a manner as to communicate with each of the plurality of via holes VH21 to VH24.

In each of the plurality of via holes VH21 to VH24, a conductive film (not shown) is embedded. Whereas, in the plurality of conductive film-embedding trenches, a plurality of third conductive films (third metal layers) CL3 are embedded, respectively. The plurality of third conductive films CL3 form a third conductive film pattern.

As mainly shown in FIG. 5, the conductive film CL3 electrically coupled with the source region of the driving transistor DT1 via the via hole VH21, the via hole VH11, and the contact hole CH1 functions as a GND line. Whereas, the conductive film CL3 electrically coupled with the source region of the driving transistor DT2 via the via hole VH22, the via hole VH12, and the contact hole CH2 functions as a GND line. Further, the conductive film CL3 electrically coupled with the gate electrode GE3 of the transfer transistor AT1 via the via hole VH23, the via hole VH17, and the contact hole CH9, and electrically coupled with the gate electrode GE4 of the transfer transistor AT2 via the via hole VH24, the via hole VH18 and the contact hole CH10 functions as the word line WL. The GND lines and the word line WL extend in such a manner as to run in parallel with each other along the transverse direction in the drawing, (i.e., between left and right in FIG. 5).

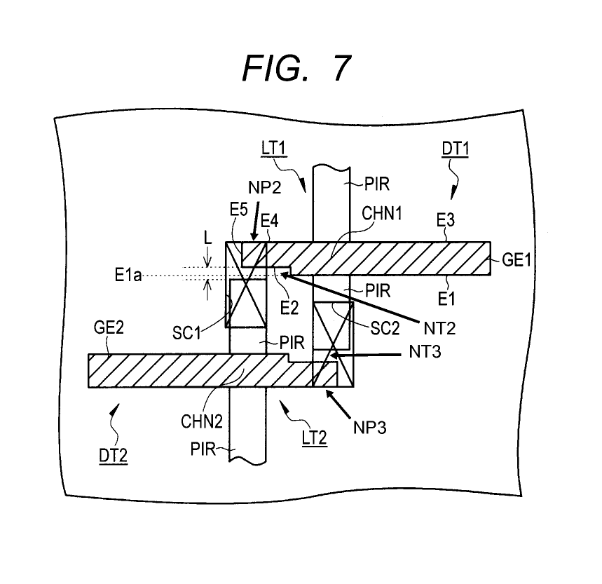

Then, a description will be given to a configuration of the shared contact in the memory cell of the SRAM in accordance with the first embodiment. FIG. 7 is a schematic plan view showing the vicinity of shared contact holes in the memory cell of the SRAM in accordance with the first embodiment on an enlarged scale.

As shown in FIG. 7, a shared contact hole SC1 reaches both the gate electrode GE1 of the load transistor LT1 and the drain region (p-type impurity region) PIR of the load transistor LT2. Meanwhile, a shared contact hole SC2 reaches both the gate electrode GE2 of the load transistor LT2 and the drain region (p-type impurity region) PIR of the load transistor LT1.

The gate electrode GE1 has non-collinear, near-side sidewalls E1 and E2 and collinear far-side sidewalls E3 and E4 opposed to each other in plan view. In plan view, the near-side sidewall E2 of the gate electrode GE1 at a portion thereof reached by the shared contact hole SC1 is located to be displaced from on an imaginary extension E1a of the near-side sidewall E1 of the gate electrode GE1 at a portion thereof located over the channel region CHN1 of the load transistor LT1 toward the far-side sidewalls E3 and E4.

The displacement of the near-side sidewall E2 with respect to the imaginary extension E1a of the near-side sidewall E1 is caused by provision of the first notch NT2 at a portion of the gate electrode GE1 with which the shared contact hole SC1 merges. In other words, in plan view, the portion of the gate electrode GE1 reached by the shared contact hole SC1 has a first notch NT2 such that the near-side sidewall E2 at the portion retreats toward the far-side sidewall E3 with respect to the imaginary extension E1a of the near-side sidewall E1.

Further, the near-side sidewall E2 is substantially in parallel with the near-side sidewall E1. Whereas, the far-side sidewall E4 of the gate electrode GE1 at a portion thereof reached by the shared contact hole SC1 and the far-side sidewall E3 of the gate electrode GE1 at a portion thereof over the channel region CHN1 are collinear and substantially located on the same straight line. Further, the minimum distance L between the end of the drain region (p-type impurity region) PIR of the load transistor LT2 and the near-side sidewall E2 in plan view is preferably 5 nm or more.

Further, the end of the first notched portion NP2 of the gate electrode GE1 is not in a tapered shape. The sidewall E5 at the end of the first notched portion NP2 of the gate electrode GE1 is opposed to the gate electrode GE4 of the transfer transistor AT2 (see FIG. 3). The sidewalls of the first notched portion NP2 are formed in parallel along the gate length direction. The distance between the near-side sidewall E2 and the far-side sidewall E4 of the gate electrode GE1, i.e., the width in the gate length direction at the first notched portion NP2 of the gate electrode GE1 is substantially constant.

Further, in FIGS. 3 and 7, the second gate electrode GE2 also has the same configuration as that of the gate electrode GE1. Specifically, as seen in FIG. 7, the second gate electrode GE2 has second notch NT3 formed in second notched portion NP3, with the first and second notches NT2, NT3 facing toward each other. As a consequence, the first and second near-side sidewalls E1, E2 of the first gate electrode GE1, and the first and second near-side sidewalls (not labeled) of the second gate electrode GE2 also face toward each other.

Additionally, in both FIGS. 3 and 7, the first load transistor LT1 shares the first gate electrode film GE1 with the first driving transistor DT1, while the second load transistor LT1 shares a second gate electrode film GE2 with the second driving transistor DT2, which is consistent with the memory cell circuit seen in FIG. 2. In the memory cell of the SRAM shown in FIG. 7, a description was given to the case where the far-side sidewall E4 of the gate electrode GE1 (or GE2) at a portion thereof reached by the shared contact hole SC1 (or SC2) is on the same straight line as the far-side sidewall E3 of the gate electrode GE1 (or GE2) at a portion thereof located over the channel region CHN1 (or CHN2).

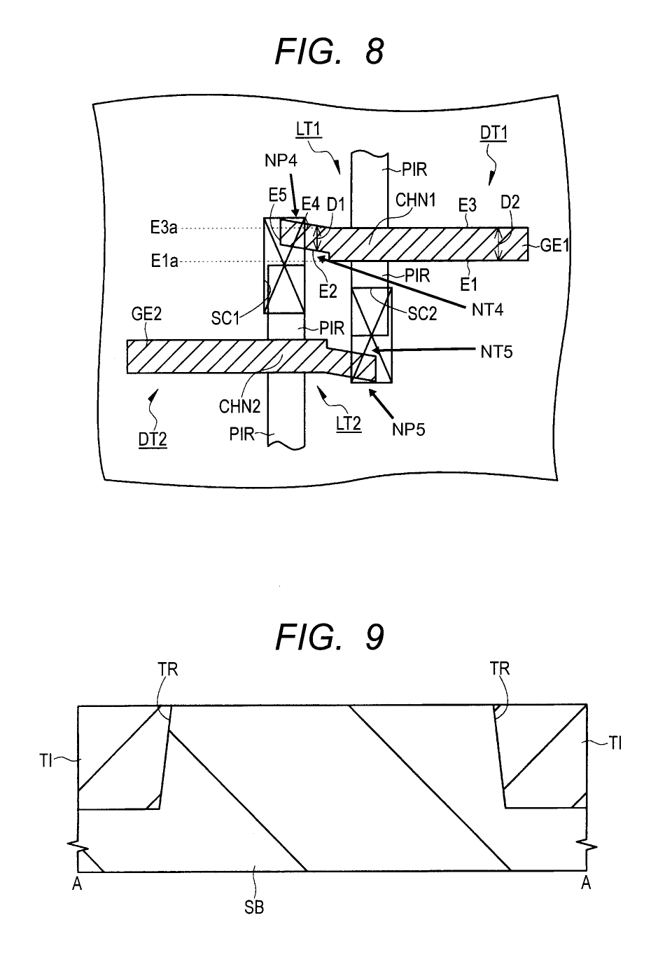

FIG. 8 is a schematic plan view of another example showing, on an enlarged scale, the vicinity of the shared contact holes in the memory cell of the SRAM in accordance with the first embodiment. A first notch NT4 is formed in the gate electrode GE1. However, the far-side sidewall E4 of the gate electrode GE1 at a portion thereof reached by the shared contact hole SC1 is not required to be on the same straight line as that for the far-side sidewall E3. Thus, herein, a description will be given to the case where the far-side sidewall E4 of the gate electrode GE1 is displaced from the imaginary extension E3a of the far-side sidewall E3 toward the opposite side from the near-side sidewall E2 side (the opposing gate electrode GE2).

As shown in the example of FIG. 8, the memory cell of the SRAM is different from the configuration of the memory cell of the SRAM shown in FIG. 7 in that the far-side sidewall E4 is displaced from the imaginary extension E3a of the far-side sidewall E3.

The far-side sidewall E4 of the gate electrode GE1, at a notched portion NP3 thereof reached by the shared contact hole SC1, is displaced toward the side opposite from near-side sidewall E2 (i.e., the side opposite from the opposing gate electrode GE2). Thus, the far-side sidewall E4 is displaced with respect to the imaginary extension E3a of gate electrode's far-side sidewall E3 (which is located over the channel region CHN1), and so does not extend in parallel with the far-side sidewall E3. In other words, in gate electrode GE1 of FIG. 8, the near-side sidewalls E1 and E2 are non-collinear and the far-side sidewalls E3 and E4 are non-collinear as well.

Further, in FIG. 8, the width D1 of the first notched portion NP4 of the gate electrode GE1 is smaller than the width D2 of the portion of the gate electrode GE1 over the channel region CHN1. The end of the first notched portion NP4 of the gate electrode GE1 is not in a tapered shape. The sidewall E5 of the end of the first notched portion NP4 of the gate electrode GE1 is opposed to the gate electrode GE4 of the transfer transistor AT2. The sidewalls of first notched portion NP4 are formed in parallel along the gate length direction. Further, the gate electrode GE2 also has the same configuration as that of the gate electrode GE1.

Other features of this example are roughly the same as those of the memory cell of the SRAM shown in FIG. 7. Thus, in the memory cell of the SRAM shown in FIG. 8, the opposing second gate electrode GE2 has a second notch NT5 formed in second notched portion NP5, with the first and second notches NT4, NT5 facing toward each other. As a consequence, the first and second near-side sidewalls E1, E2 of the first gate electrode GE1, and the first and second near-side sidewalls (not labeled) of the second gate electrode GE2 also face toward each other.

A method for manufacturing a semiconductor device in accordance with the first embodiment will be described step by step by reference to FIGS. 9 to 19.

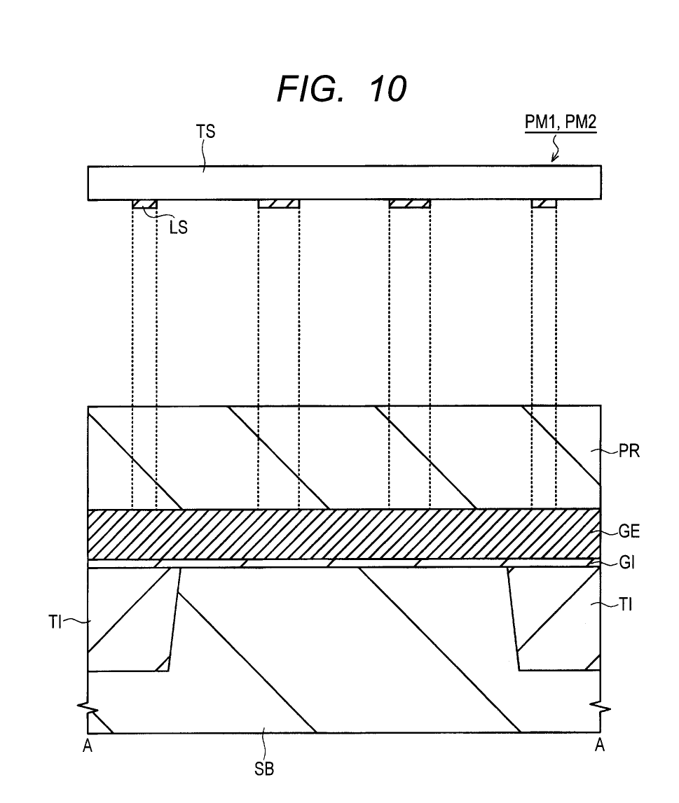

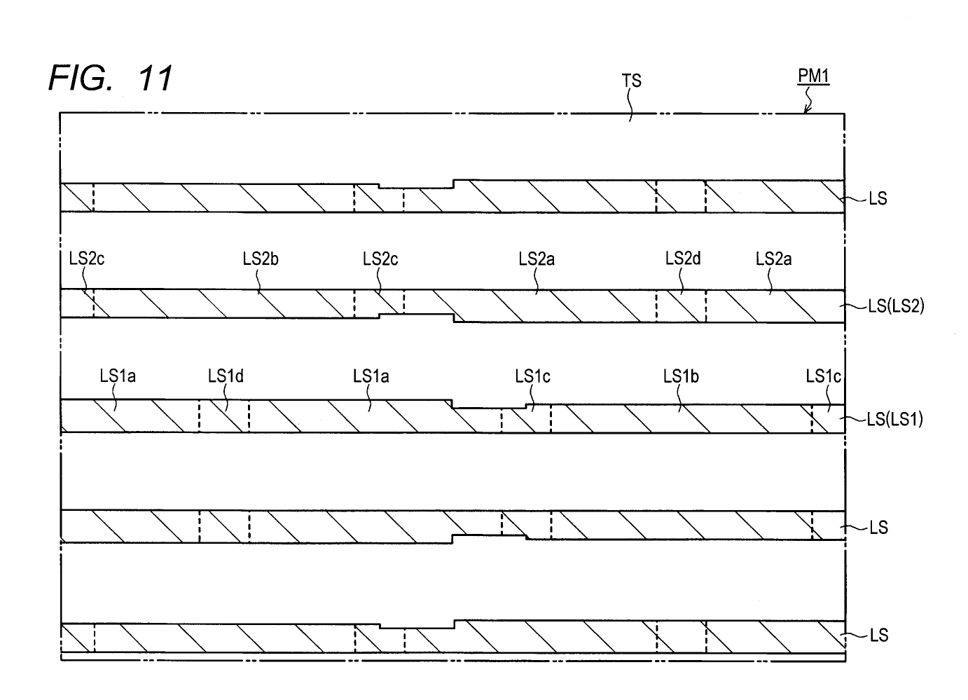

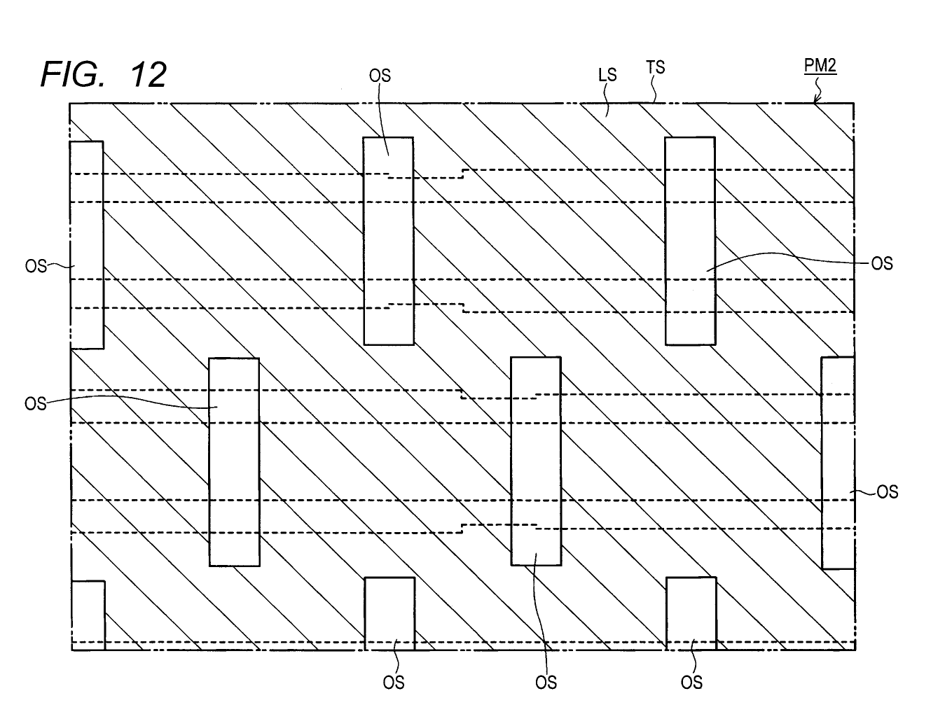

FIGS. 9, 10, and 13 to 19 are each an essential cross-sectional view showing the method for manufacturing a semiconductor device in accordance with the first embodiment step by step, and a cross-sectional view corresponding to the cross section of FIG. 6. FIGS. 11 and 12 are each a plan view schematically showing the configuration of a photomask for use in the method for manufacturing a semiconductor device in accordance with the first embodiment.

First, as shown in FIG. 9, in the main surface of the semiconductor substrate SB, isolation trenches TR are formed. In each trench TR, a filling TI including silicon oxide is embedded, thereby to form an element isolation part including STI. Further, although not shown, in the semiconductor substrate SB, there are formed p-type wells PW1 and PW2 and an n-type well NW.

Then, as shown in FIG. 10, over the main surface of the semiconductor substrate SB, a gate insulation film G1 and a gate electrode conductive film GE are formed. Subsequently, over the gate electrode conductive film GE, for example, a positive type photoresist PR is applied.

The photoresist PR is exposed through a pattern of the photomask PM1 shown in FIG. 11 (first exposure). The photomask PM1 has a substrate TS for transmitting an exposure light therethrough, and a plurality of light shield patterns (e.g., chromium films) LS for blocking the transmission of the exposure light, formed over the substrate TS.

In the photomask PM1, the plurality of light shield patterns LS are formed so that light shield portions and the like are located at positions corresponding to the patterns of the gate electrodes.

For example, a first light shield part LS1 includes a first pattern portion LS1a, a second pattern portion LS1b, a third pattern portion LS1c, and a fourth pattern portion LS1d. The first pattern portion LS1a corresponds to a portion of the gate electrode GE1 common to the load transistor LT1 and the driving transistor DT1. The second pattern portion LS1b corresponds to a portion of the gate electrode GE4 of the transfer transistor AT2. The third pattern portion LS1c corresponds to a portion interposed between the first pattern portion LS1a and the second pattern portion LS1b. The fourth pattern portion LS corresponds to a portion between the adjacent gate electrodes GE1. The first pattern portion LS1a and the third pattern portion LS1c have a notch such as to correspond to the notched portion of the gate electrode GE1.

Further, the second light shield part LS2 includes a first pattern portion LS2a, a second pattern portion LS2b, a third pattern portion LS2c, and a fourth pattern portion LS2d. The first pattern portion LS2a corresponds to a portion of the gate electrode GE2 common to the load transistor LT2 and the driving transistor DT2. The second pattern portion LS2b corresponds to a portion of the gate electrode GE3 of the transfer transistor AT1. The third pattern portion LS2c corresponds to a portion interposed between the first pattern portion LS2a and the second pattern portion LS2b. The fourth pattern portion LS2d corresponds to a portion between the adjacent gate electrodes GE2. The first pattern portion LS2a and the third pattern portion LS2c have a notch such as to correspond to a portion of the gate electrode GE2 at which a notch is formed.

Subsequently, the photoresist PR is exposed through a pattern of the photomask PM2 shown in FIG. 12 (second exposure). The photomask PM2 has a substrate TS for transmitting an exposure light therethrough, and a plurality of light shield patterns (e.g., chromium films) LS for blocking the transmission of the exposure light, formed over the substrate TS.

In the photomask PM2, a light shield pattern LS is formed such that openings OS are located at positions corresponding to, for example, the third pattern portion LS1c and the fourth pattern portion LS1d of the light shield part LS1, and the third pattern portion LS2c and the fourth pattern portion LS2d of the light shield part LS2 formed in the photomask PM1. The opening OS is, for example, in a tetragon form (thin rectangular form or rectangular form).

After the first exposure using the photomask PM1, and the second exposure using the photomask PM2, the photoresist PR is developed. Herein, the first exposure was performed using the photomask PM1, and the second exposure was performed using the photomask PM2. However, it is also acceptable that the first exposure is performed using the photomask PM2, and that the second exposure is performed using the photomask PM1.

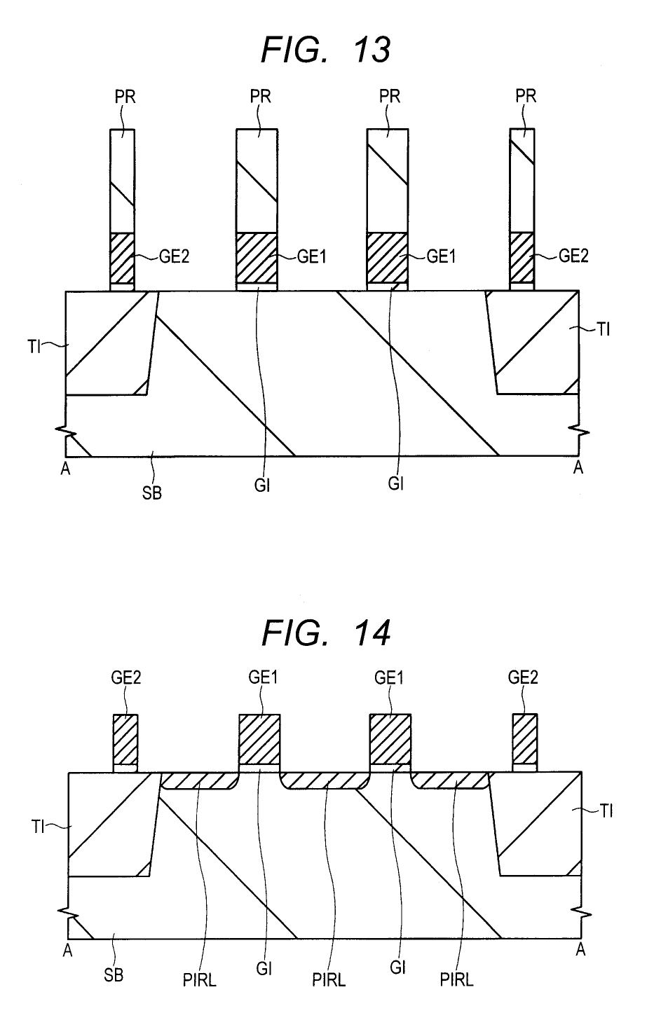

Then, as shown in FIG. 13 (cross-section along lines XIII-XIII of FIG. 11 after PR removal), regions of the photoresist PR to which the exposure light has been applied by the development are removed, thereby to pattern the photoresist PR. This removes the third pattern portions LS1c, LS2c and the fourth pattern portions LS1d, LS2d. As a result, there are formed a resist pattern corresponding to a portion of the gate electrode GE1 common to the load transistor LT1 and the driving transistor DT1, a resist pattern corresponding to a portion of the gate electrode GE2 common to the load transistor LT2 and the driving transistor DT2, a resist pattern corresponding to a portion of the gate electrode GE3 of the transfer transistor AT1 (not seen in the cross-section of FIG. 13, and a resist pattern corresponding to a portion of the gate electrode GE4 of the transfer transistor AT2 (also not seen in the cross-section of FIG. 13).

The resist pattern at a position corresponding to the portion of the gate electrode GE1 reached by the shared contact hole SC1, and the resist pattern at a position corresponding to the portion of the gate electrode GE2 reached by the shared contact hole SC2 respectively have notches. Further, in the resist patterns at positions corresponding to the opposite ends in the gate width directions of respective gate electrodes GE1 to GE4, the sidewalls thereof are formed in parallel along respective gate length directions.

With the patterning of the photoresist PR as a mask, the gate electrode conductive film GE is etched. As a result, the gate electrode conductive film GE is patterned, so that there are formed the gate electrode GE1 common to the load transistor LT1 and the driving transistor DT1, the gate electrode GE2 common to the load transistor LT2 and the driving transistor DT2, the gate electrode GE3 of the transfer transistor AT1, the gate electrode GE4 of the transfer transistor AT2, and the like. Then, the pattern of the photoresist PR is removed by ashing or the like.

Then, as shown in FIG. 14, with the gate electrodes GE1 to GE4, and the like as a mask, impurities are ion-implanted, or are subjected to other procedures. As a result, in the main surface of the semiconductor substrate SB, low concentration regions of source/drain regions are formed. At this step, n-type impurities and p-type impurities are separately implanted, thereby to form n-type low concentration regions NIRL and p-type low concentration regions PIRL.

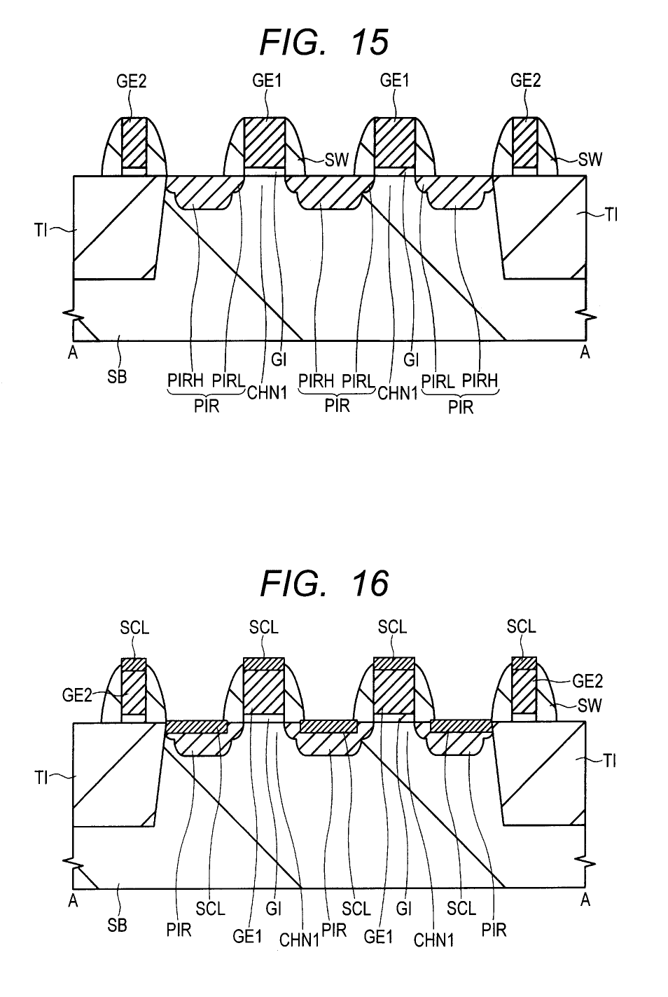

Then, as shown in FIG. 15, an insulation film for sidewall is formed in such a manner as to cover the tops of the gate electrodes GE1 to GE4. As the material for the insulation film, only silicon oxide may be formed, or silicon nitride may be formed after formation of silicon oxide. Then, the entire surface is etched back until the main surface of the semiconductor substrate SB is exposed. As a result, at respective sidewalls of the gate electrodes GE1 to GE4, the insulation film for sidewall is left, thereby to form sidewalls SW.

With the sidewalls SW, the gate electrodes GE1 to GE4, and the like as masks, impurities are ion-implanted, or are subjected to other procedures. As a result, in the main surface of the semiconductor substrate SB, high concentration regions of source/drain regions are formed. At this step, n-type impurities and p-type impurities are separately implanted, thereby to form n-type high concentration regions NIRH and p-type high concentration regions PIRH.

Thus, the n-type low concentration regions NIRL and the n-type high concentration regions NIRH form n-type impurity regions NIR to be source/drain regions having a LDD (Lightly Doped Drain) structure. Whereas, the p-type low concentration regions PIRL and the p-type high concentration regions PIRH form p-type impurity regions PIR to be source/drain regions having a LDD structure.

Then, as shown in FIG. 16, over the main surface of the semiconductor substrate SB, a refractory metal film is formed, and is subjected to a heat treatment. As a result, over the gate electrodes GE1 to GE4 and over the main surface of the semiconductor substrate SB, silicide films SCL are formed. Then, portions of the refractory metal film which have not become silicide are removed. Herein, as the materials for the refractory metal film, there may be used Ni, Co, Pt, Pd, Hf, V, Er, Ir, Yb, or two or more materials selected from these.

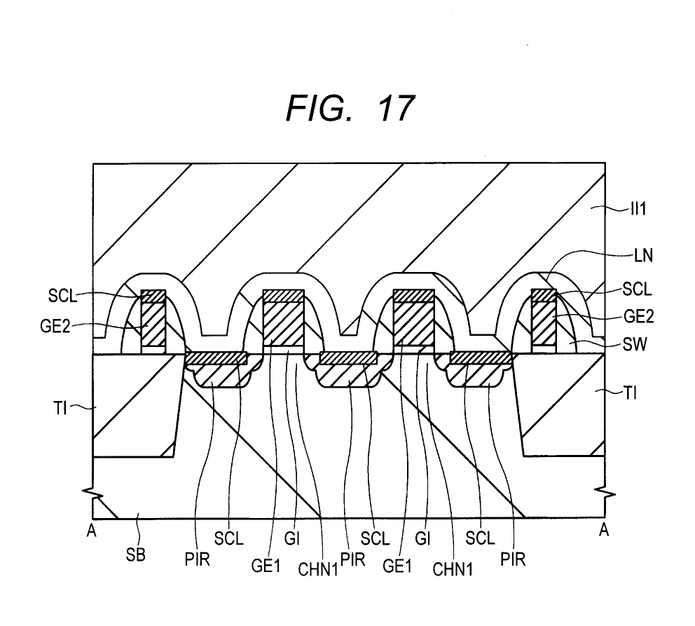

Then, as shown in FIG. 17, a first liner nitride film LN and a first interlayer insulation film II1 including silicon oxide are sequentially stacked and formed over the main surface of the semiconductor substrate SB in such a manner as to cover the gate electrodes GE1 to GE4, the sidewalls SW, and the like.

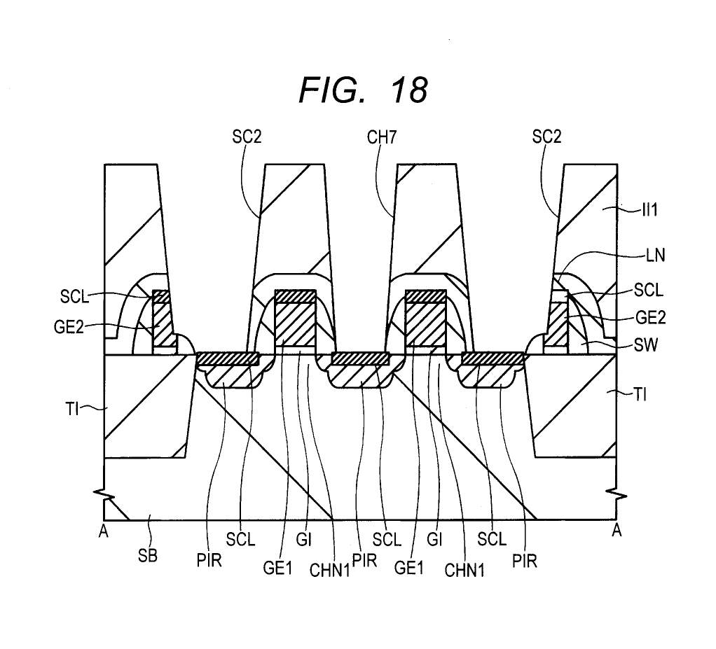

Then, as shown in FIG. 18, in the first liner nitride film LN and the first interlayer insulation film II1, shared contact holes SC1 and SC2, contact holes CH1 to CH10, and the like are formed using a photolithography technology and an etching technology.

Herein, the shared contact hole SC1 is formed so as to reach both of the gate electrode GE1 of the load transistor LT1 and the drain region PIR of the load transistor LT2 (so as to expose both surfaces). Whereas, the shared contact hole SC2 is formed so as to reach both of the gate electrode GE2 of the load transistor LT2 and the drain region PIR of the load transistor LT1 (so as to expose both surfaces).

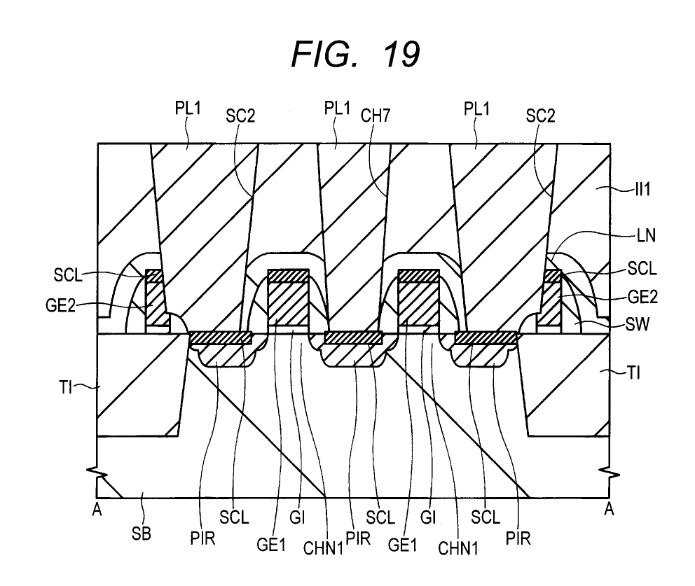

Then, as shown in FIG. 19, a conductive film including tungsten (W) is formed over the interlayer insulation film II1 by, for example, CVD (Chemical Vapor Deposition) in such a manner as to fill the shared contact holes SC1 and SC2, the contact holes CH1 to CH10, and the like. Then, the conductive film is etched back until the surface of the first interlayer insulation film II1 is exposed. As a result, there are formed conductive films PL1 as contact plugs which fill the shared contact holes SC1 and SC2, the contact holes CH1 to CH10, and the like.

Then, formation of the insulation film and formation of the conductive film are repeated, thereby to manufacture the memory cell of the SRAM in accordance with the first embodiment shown in FIG. 6.

Incidentally, in the first embodiment, the photoresist PR was subjected to two exposures (first exposure using the photomask PM1 and second exposure using the photomask PM2). Then, development was carried out, thereby to pattern the photoresist PR. With the resist pattern as a mask, the gate electrode conductive film GE was etched. However, this method is not exclusive. For example, the following procedure is also acceptable: first, the first photoresist is subjected to first exposure (exposure using the photomask PM1), and development is carried out, thereby to form a first resist pattern; then with the first resist pattern as a mask, the gate electrode conductive film GE is etched. Subsequently, after removal of the first photoresist, the second photoresist is subjected to second exposure (exposure using the photomask PM2), and development is carried out, thereby to form a second resist pattern; then with the second resist pattern as a mask, the gate electrode conductive film GE is etched.

Thus, at the portion of the gate electrode GE1 of the load transistor LT1 reached by the shared contact hole SC1, in plan view (see FIGS. 3 and 7), the near-side sidewall E2 at the notched portion NP2 retreats toward the far-side sidewall E3 with respect to the imaginary extension E1a of the near-side sidewall E1. This can ensure a wider contact area between the shared contact hole SC1 and the drain region PIR of the load transistor LT2 than that in the case where the near-side sidewall E2 and the near-side sidewall E1 are collinear and thus located on the same line. Further, for forming the gate electrode GE1 of the load transistor LT1, the resist pattern PR1 is formed using two exposures. As a result, the portion of the gate electrode GE1 reached by the shared contact hole SC1 is not in a tapered shape, and can have a given width along the gate length direction even when the near-side sidewall E2 at the portion retreats toward the far-side sidewall E3 with respect to the imaginary extension E1a of the near-side sidewall E1 in plan view. This also applies to the portion of the gate electrode GE2 of the load transistor LT2 reached by the shared contact hole SC2.

These can stably provide a conduction between the conductive films PL1 embedded in the insides of the shared contact holes SC1 and SC2 and the drain region PIR of the load transistors LT1 and LT2, and a conduction between the conductive films PL1 embedded in the insides of the shared contact holes SC1 and SC2 and the gate electrodes GE1 and GE2 of the load transistors LT1 and LT2.

### Second Embodiment

In various transistors (the transfer transistors AT1 and AT2, the driving transistors DT1 and DT2, and the load transistors LT1 and LT2) forming the memory cell of the SRAM in accordance with the first embodiment, as described by reference to, for example, FIGS. 6, and 9 to 19, after the formation of the gate insulation films and the gate electrodes, the source/drain regions were formed. However, it is also possible to form gate insulation films and gate electrodes after the formation of source/drain regions. By forming gate insulation films and gate electrodes after the formation of source/drain regions, it becomes possible to form the gate electrodes with only metal materials. This can implement a further higher speed of the SRAM in addition to the densification of the memory cell of the SRAM.

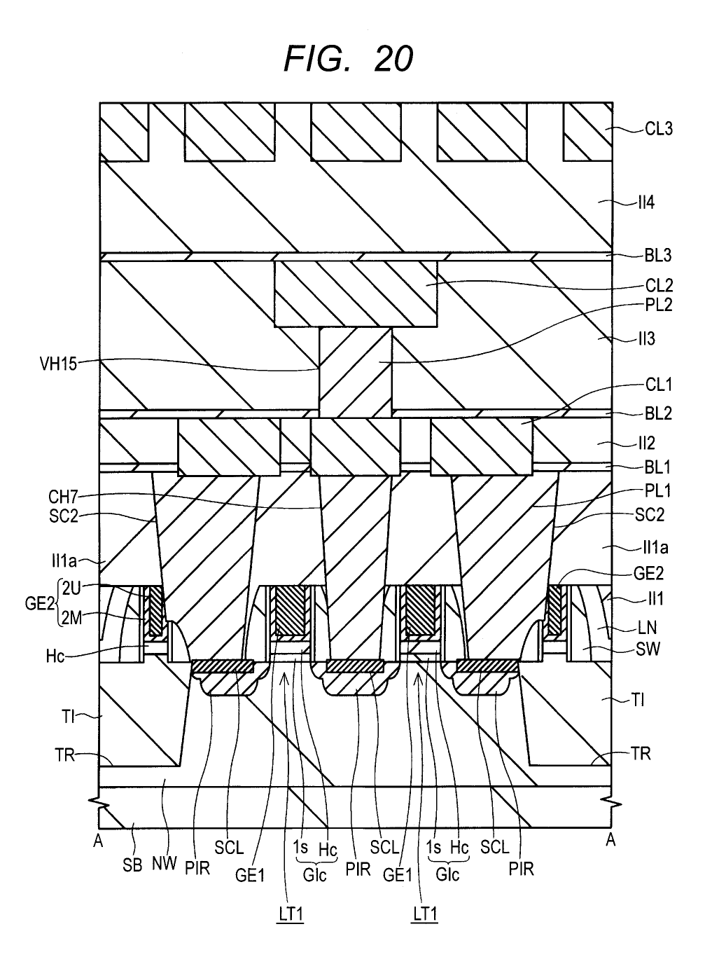

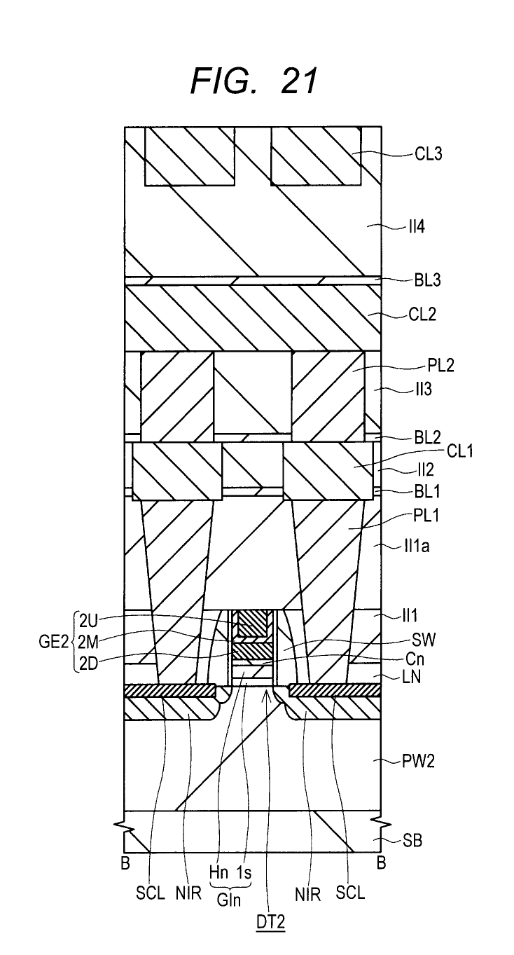

One example of the configuration of the SRAM in accordance with the present second embodiment will be described by reference to FIGS. 20 to 22. FIG. 20 is a schematic cross-sectional view (a schematic cross-sectional view of load transistors) along line A-A of FIGS. 3 to 5 (schematic plan views each showing the planar layout configuration of the memory cell of the SRAM in accordance with the first embodiment). FIG. 21 is a schematic cross-sectional view (a schematic cross-sectional view of a driving transistor) along line B-B of FIGS. 3 to 5. FIG. 22 is a schematic cross-sectional view (a schematic cross-sectional view of a driving transistor and a load transistor) along line C-C′ of FIGS. 3 to 5.

Herein, a description will be given to various transistors in each of which a gate insulation film includes a High-k material with a high relative dielectric constant, and a gate electrode includes a metal material. For the gate insulation film, a High-k film is adopted in place of a related-art SiO₂ film or a SiON film. As a result, it is possible to suppress the gate leakage current increased due to the tunneling effect, and to reduce the equivalent oxide thickness (EOT) for improving the gate capacitance. This can enhance the driving capability of the field effect transistor.

The various transistors forming the memory cell of the SRAM in accordance with the present second embodiment and the various transistors forming the memory cell of the SRAM described above are different from each other mainly in terms of the gate electrode structure. Below, a description will be given to the structures of respective gate electrodes of the transfer transistors AT1 and AT2 and the driving transistors DT1 and DT2 including nMISs, and the structures of respective gate electrodes of the load transistors LT1 and LT2 including pMISs.

First, respective gate structures of the transfer transistors AT1 and AT2 and the driving transistors DT1 and DT2 including nMISs will be described by reference to FIGS. 21 and 22. FIGS. 21 and 22 show the driving transistors DT1 and DT2, but the same also applies to the transfer transistors AT1 and AT2.

As shown in FIGS. 21 and 22, over the p-type well regions PW1 and PW2 formed in the main surface of the semiconductor substrate SB, there is formed a gate insulation film GIn including a lamination film of an oxide film 1s and a high dielectric constant film Hn. The oxide film 1s is, for example, a SiO₂ film. When the semiconductor substrate SB and the high dielectric constant film Hn are in direct contact with each other, the mobility of each of the transfer transistors AT1 and AT2 and the driving transistors DT1 and DT2 may be reduced. However, by interposing the oxide film 1s between the semiconductor substrate SB and the high dielectric constant film Hn, it is possible to prevent the reduction of the mobility. As the high dielectric constant film Hn, there is used a hafnium type insulation film such as a HfOₓ film, a HfON film, a HfSiOₓ film, or a HfSiON film. The hafnium type insulation film contains a metallic element such as La for adjusting the work function, and obtaining each desirable threshold voltage of the transfer transistors AT1 and AT2 and the driving transistors DT1 and DT2. Therefore, as the constituent material of the typical high dielectric constant film Hn, for example, HfLaON can be mentioned.

Over the gate insulation film GIn, a cap film Cn is formed. The cap film Cn is, for example, a LaO film, and is formed in order to add a metallic element for obtaining each threshold voltage of the transfer transistors AT1 and AT2 and the driving transistors DT1 and DT2, i.e., La to the hafnium type insulation film forming the high dielectric constant film Hn. Incidentally, as the metallic element to be added to the hafnium type insulation film forming the high dielectric constant film Hn, La was mentioned. However, other metallic elements are also acceptable. Therefore, as the cap film Cn, there can be used a La₂O₅ film, a La film, a MgO film, a Mg film, a BiSr film, a SrO film, a Y film, a Y₂O₃ film, a Ba film, a BaO film, a Se film, a ScO film, or the like. Incidentally, the metallic elements forming the cap film Cn may be entirely added to the high dielectric constant film Hn.

Over the cap film Cn, the gate electrodes GE1 and GE2 including a plurality of stacked metal films are formed. The gate electrodes GE1 and GE2 each have a three-layered structure of a lamination of, for example, a bottom layer gate electrode 2D, a middle layer gate electrode 2M, and a top layer gate electrode 2U. The bottom layer gate electrode 2D includes, for example, a TiN film. Whereas, the middle layer gate electrode 2M is a metal film provided for adjusting the threshold voltages of the load transistors LT1 and LT2 including pMISs (adjusting the work function of the high dielectric constant film), and includes, for example, a TiN film. Further, the top layer gate electrode 2U includes a metal film containing, for example, Al. Over the gate electrodes GE1 and GE2, a silicide film SCL as seen in the first embodiment (‘SCL’ over GE1 and GE2 in FIG. 6) is not formed.

Then, each gate structure of the load transistors LT1 and LT2 including pMISs will be described by reference to FIGS. 20 and 22.

As shown in FIGS. 20 and 22, over an n-type well region NW formed in the main surface of the semiconductor substrate SB, there is formed a gate insulation film GIc including a lamination film of an oxide film 1s and a high dielectric constant film Hc. As the high dielectric constant film Hc, there is used a hafnium type insulation film such as a HfOₓ film, a HfON film, a HfSiOₓ film, or a HfSiON film.

Over the gate insulation film GIc, the gate electrodes GE1 and GE2 are formed. The gate electrodes GE1 and GE2 each have a two-layered structure of a lamination of, for example, a middle layer gate electrode 2M and a top layer gate electrode 2U. By the middle layer gate electrode 2M formed over the high dielectric constant film Hc, the work function can be adjusted, thereby to adjust the threshold voltages of the load transistors LT1 and LT2. Over the gate electrodes GE1 and GE2, the silicide film SCL as seen in the first embodiment (see FIG. 6) is not formed.

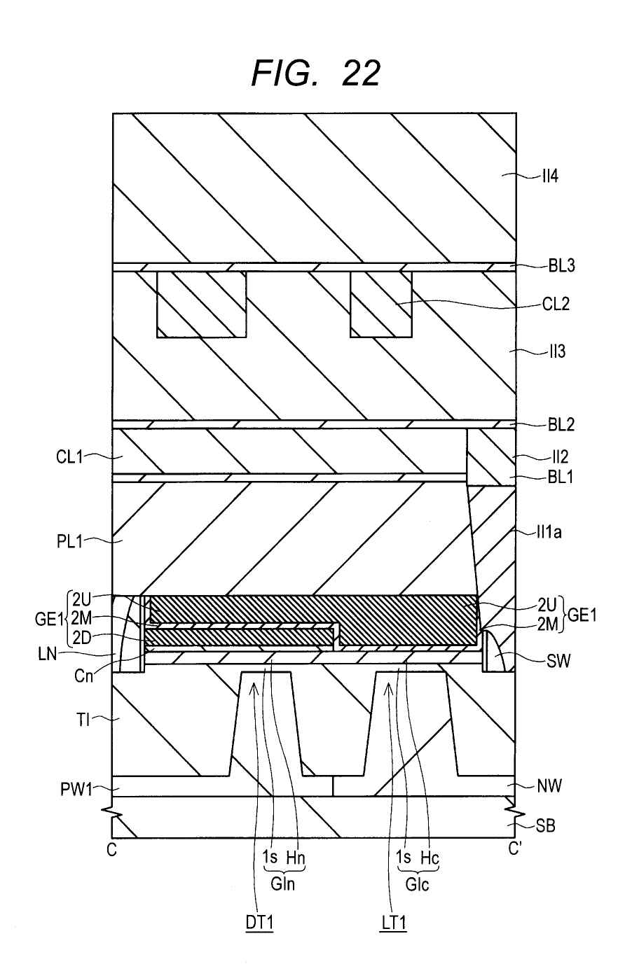

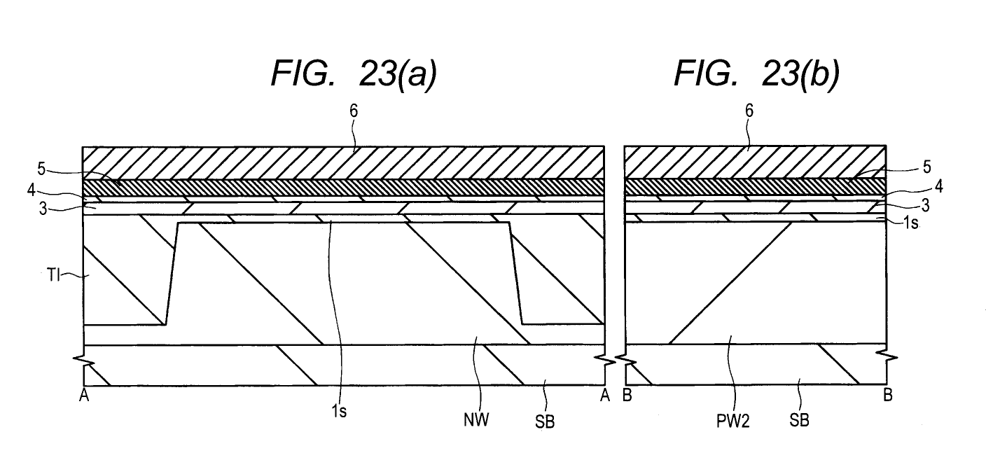

Then, a method for manufacturing the semiconductor device in accordance with the present second embodiment will be described step by step by reference to FIGS. 23A and 23B to 32A and 32B. FIGS. 23A and 23B to 32A and 32B are cross-sectional views corresponding to the cross sections of FIGS. 20 and 21.

First, as shown in FIGS. 23A and 23B, by the same manufacturing step as that in the first embodiment, in the semiconductor substrate SB, the p-type well regions PW1 and PW2 and the n-type well region NW are formed. Further, the element isolation part and the oxide film 1s are formed.

Then, over the main surface of the semiconductor substrate SB, for example, a HfON film 3 is formed. The HfON film 3 is formed using, for example, a CVD method or an ALD (Atomic Layer Deposition) method. The thickness thereof is, for example, about 1 nm. There can be used, for example, another hafnium type insulation film such as a HfSiON film, a HfSiO film, or a HfO₂ film in place of the HfON film 3.

Subsequently, after performing a nitriding treatment, over the HfON film 3, for example, a LaO film 4 (cap film Cn) is deposited. The LaO film 4 is formed using, for example, a sputtering method. The thickness thereof is, for example, about 0.1 to 1.5 nm. Subsequently, over the LaO film 4, for example, a TiN film 5 is deposited. The TiN film 5 is formed using, for example, a sputtering method. The thickness thereof is, for example, about 5 to 15 nm. Subsequently, over the TiN film 5, for example, a first polycrystalline Si film 6 is deposited.

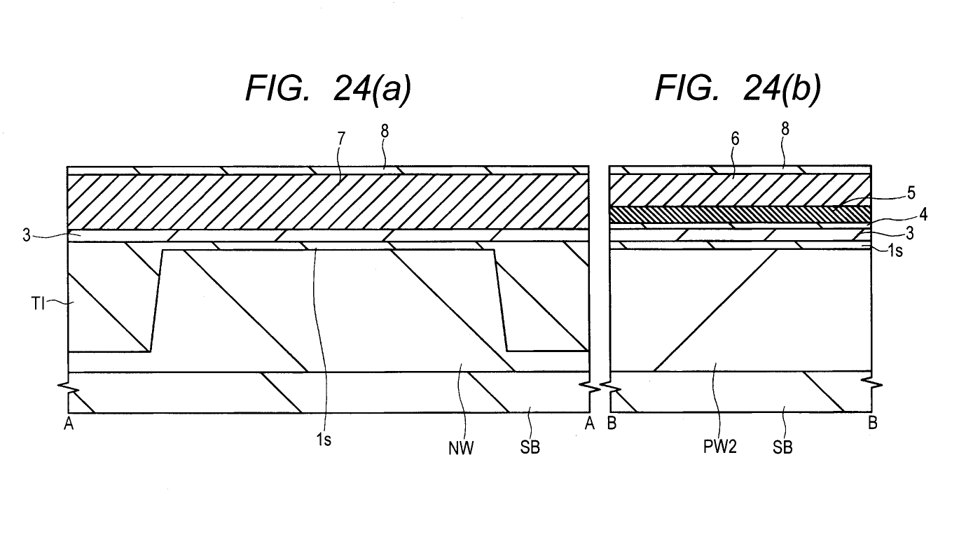

Then, as shown in FIGS. 24A and 24B, after removing the first polycrystalline Si film 6, the TiN film 5, and the LaO film 4 in the n-type well NW region, over the main surface of the semiconductor substrate SB, for example, a second polycrystalline Si film 7 is deposited. The second polycrystalline Si film 7 is formed with a larger thickness than that of the first polycrystalline Si film 6. Subsequently, the surface of the second polycrystalline Si film 7 is polished by a CMP (Chemical Mechanical Polishing) method. As a result, the surface over both the n-type well NW region and the p-type well PW2 region is planarized. Then, a dummy insulation film 8 including, for example, silicon nitride, silicon oxide, or silicon oxynitride is formed over the second polycrystalline Si film 7.

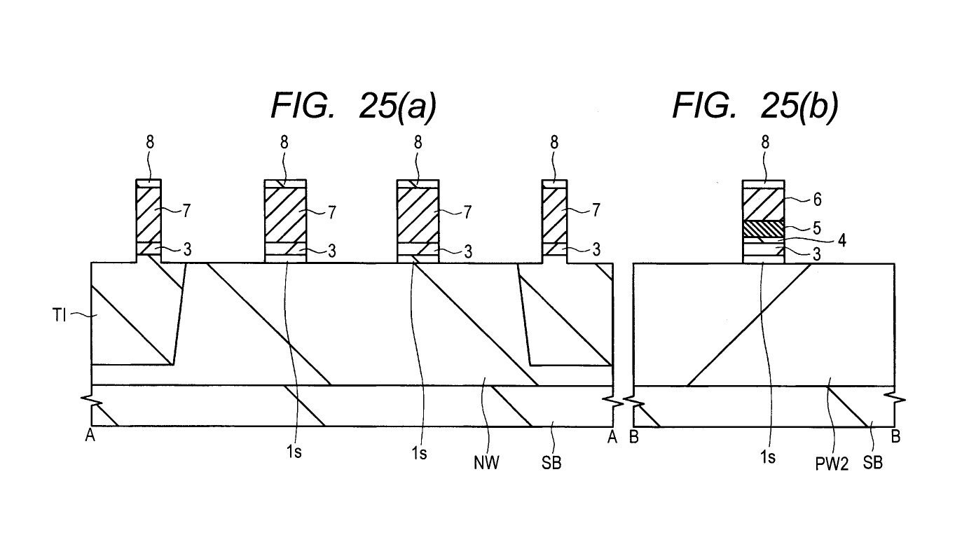

Then, as shown in FIGS. 25A and 25B, using a photolithography method and a dry etching method, the dummy insulation film 8, the second polycrystalline Si film 7, the first polycrystalline Si film 6, the TiN film 5, the LaO film 4, the HfON film 3, and the oxide film 1s are sequentially processed.

As a result, in each forming region of the transfer transistors AT1 and AT2 and the driving transistors DT1 and DT2, there is formed a dummy gate including a gate insulation film including a lamination film of the oxide film 1s and the HfON film 3, a dummy gate electrode including a lamination film of the LaO film 4, the TiN film 5, the first polycrystalline Si film 6, and the second polycrystalline Si film (7), and the dummy insulation film 8. Whereas, in each forming region of the load transistors LT1 and LT2, there is formed a dummy gate including a gate insulation film including a lamination film of the oxide film 1s and the HfON film 3, a dummy gate electrode including the second polycrystalline Si film 7, and a dummy insulation film 8.

Herein, by two exposures using the two photomasks PM1 and PM2 described in the first embodiment, the photoresist is patterned. As a result, there are formed a resist pattern corresponding to the portion of the dummy gate common to the load transistor LT1 and the driving transistor DT1, a resist pattern corresponding to the portion of the dummy gate common to the load transistor LT2 and the driving transistor DT2, a resist pattern corresponding to the portion of the dummy gate of the transfer transistor AT1, and a resist pattern corresponding to the portion of the dummy gate of the transfer transistor AT2.

The resist pattern at a position corresponding to the portion of the dummy gate common to the load transistor LT1 and the driving transistor DT1 reached by the shared contact hole SC1, and the resist pattern at a position corresponding to the portion of the dummy gate common to the load transistor LT2 and the driving transistor DT2 reached by the shared contact hole SC2 respectively have notched portions. Further, in the resist patterns at positions corresponding to the opposite ends in their gate width directions of respective gate electrodes GE1 to GE4, the sidewalls thereof are formed in parallel along their gate length directions.

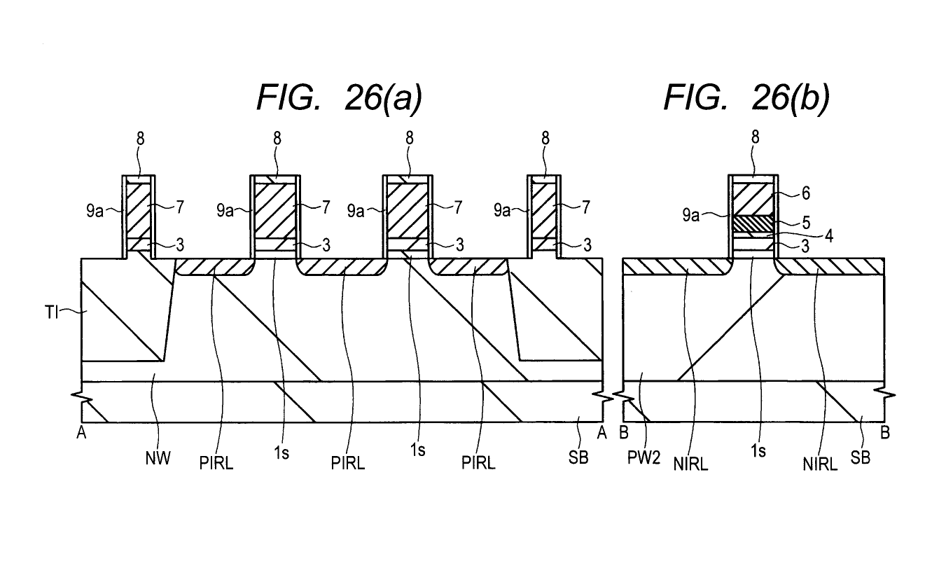

Then, as shown in FIGS. 26A and 26B, at respective sidewalls of respective dummy gates, offset sidewalls 9a are formed. The offset sidewalls 9a include silicon nitride or silicon oxide formed using, for example, a CVD method. The thickness thereof is, for example, about 5 nm.

Subsequently, with the dummy gates and the like as masks, impurities are ion-implanted, or are subjected to other procedures. As a result, in the main surface of the semiconductor substrate SB, low concentration regions of source/drain regions are formed. At this step, n-type impurities and p-type impurities are separately implanted, thereby to form n-type low concentration regions NIRL and p-type low concentration regions PIRL.

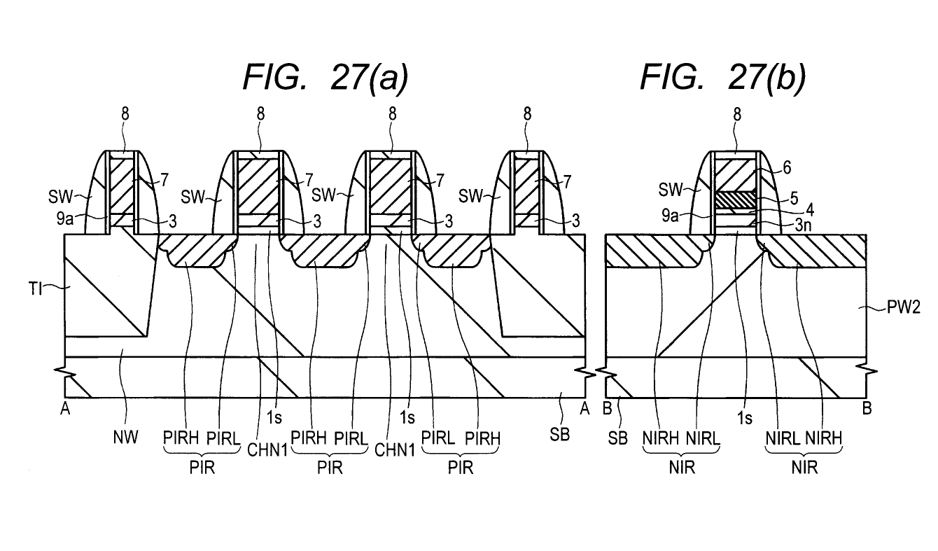

Then, as shown in FIGS. 27A and 27B, at respective sidewalls of the dummy gates, sidewalls SW are formed via the offset sidewalls 9a. Over the main surface of the semiconductor substrate SB, for example, only silicon oxide is formed, or an insulation film including silicon nitride is formed after formation of silicon oxide. Then, the entire surface is etched back until the main surface of the semiconductor substrate SB is exposed. As a result, at respective sidewalls of respective dummy gates, the sidewalls SW are formed.

With the sidewalls SW, the dummy gates, and the like as masks, impurities are ion-implanted, or are subjected to other procedures. As a result, in the main surface of the semiconductor substrate SB, high concentration regions of source/drain regions are formed. At this step, n-type impurities and p-type impurities are separately implanted, thereby to form n-type high concentration regions NIRH and p-type high concentration regions PIRH.

Subsequently, a heat treatment is performed. By the heat treatment, the n-type impurities introduced into the n-type low concentration regions NIRL and the n-type high concentration regions NIRH are activated, and the p-type impurities introduced into the p-type low concentration regions PIRL and the p-type high concentration regions PIRH are activated. Thus, the n-type low concentration regions NIRL and the n-type high concentration regions NIRH form n-type impurity regions NIR to be source/drain regions having a LDD structure. Whereas, the p-type low concentration regions PIRL and the p-type high concentration regions PIRH form p-type impurity regions PIR to be source/drain regions having a LDD structure.

Further, simultaneously, by the heat treatment, La is thermally diffused from the LaO film 4 into the HfON film 3, so that the HfON film 3 in the p-type well region PW2 becomes a HfLaON film 3n (high dielectric substance Hn). At this step, the heat treatment may be carried out so that the LaO film 4 is left. However, the heat treatment may also be carried out so that the LaO film 4 entirely reacts. Subsequent drawings show the LaO film 4 being partially left.

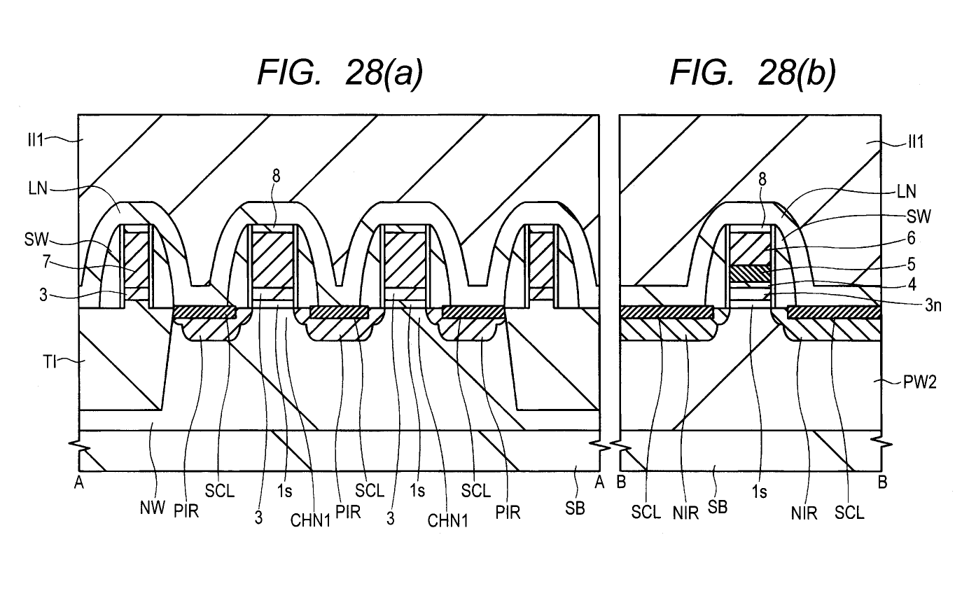

Then, as shown in FIGS. 28A and 28B, over the main surface of the semiconductor substrate SB, a refractory metal film is formed, and is subjected to a heat treatment. As a result, over the main surface of the semiconductor substrate SB, silicide films SCL are formed. Then, portions of the refractory metal film which have not become silicide are removed. Herein, as the materials for the refractory metal film, there may be used Ni, Co, Pt, Pd, Hf, V, Er, Ir, Yb, or two or more materials selected from these.

Then, in such a manner as to cover the dummy gates, the sidewalls SW, and the like, over the main surface of the semiconductor substrate SB, a liner nitride film LN and a first interlayer insulation film II1 including silicon oxide are sequentially stacked and formed.

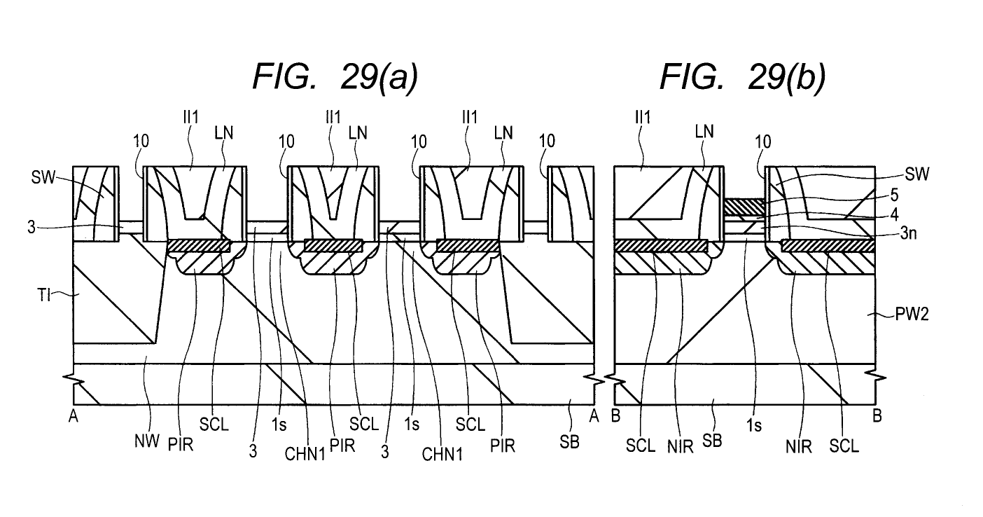

Then, as shown in FIGS. 29A and 29B, the first interlayer insulation film II1, the liner nitride film LN, and the dummy insulation film 8 are polished using, for example, a CMP method until the second polycrystalline Si film 7 is exposed.

Subsequently, the exposed first polycrystalline Si film 6 and second polycrystalline Si film 7 are removed. As a result, at sites at which the dummy gates are formed, concave parts 10 are formed. At each bottom surface of the concave parts 10 in the forming regions of the transfer transistors AT1 and AT2 and the driving transistors DT1 and DT2, the TiN film 5 is exposed. At each bottom surface of the concave parts 10 of the forming regions of the load transistors LT1 and LT2, the HfON film 3 is exposed.

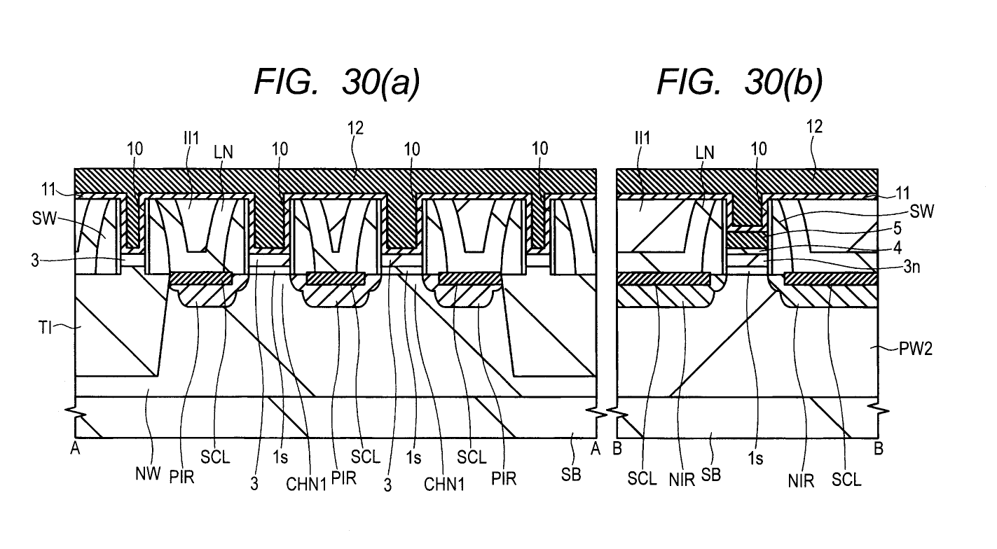

Then, as shown in FIGS. 30A and 30B, over the main surface of the semiconductor substrate SB, a first metal film 11 for adjusting the work functions of the load transistors LT1 and LT2 is deposited. The first metal film 11 is, for example, a TiN film. The thickness thereof is, for example, 15 nm, which is a thickness not fully filling the inside of each concave part 10. Subsequently, over the first metal film 11, a second metal film 12 is formed in such a manner as to fill the inside of each concave part 10. The second metal film 12 is a metal film containing, for example, Al. The thickness thereof is, for example, 100 nm.

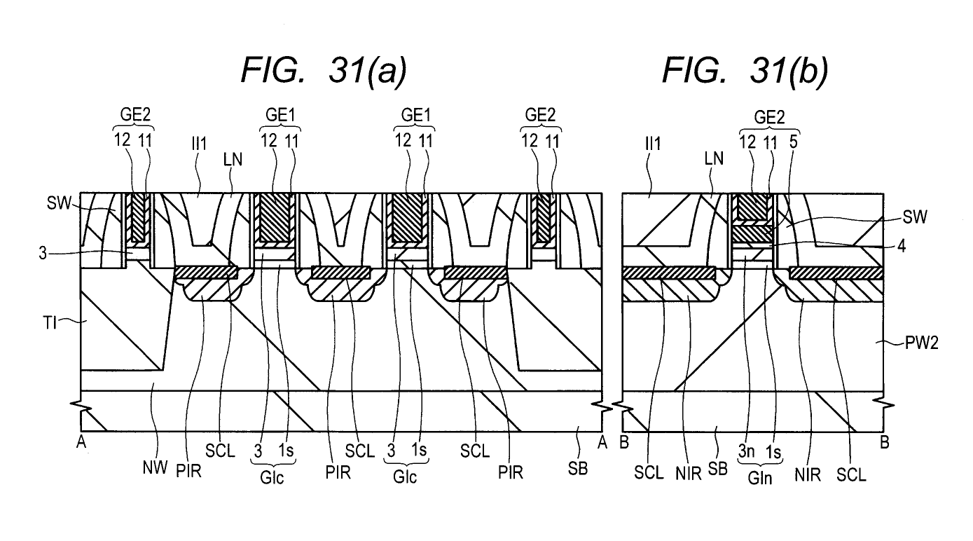

Then, as shown in FIGS. 31A and 31B, the first metal film 11 and the second metal film 12 are polished using, for example, a CMP method. As a result, in the inside of each concave part 10, the first metal film 11 and the second metal film 12 are embedded.

As a result, in each forming region of the transfer transistors AT1 and AT2 and the driving transistors DT1 and DT2, there is formed a gate in a Nch gate stack structure including a gate insulation film GIn including a lamination film of the oxide film 1s and the HfLaO film 3n (high dielectric constant film Hn), and the gate electrode GE1 or GE2 including a lamination film of the LaO film 4 (cap film Cn), and the TiN film 5 (bottom layer gate electrode 2D), the first metal film 11 (middle layer gate electrode 2M) and the second metal film 12 (top layer gate electrode 2U). Whereas, in each forming region of the load transistors LT1 and LT2, there is formed a gate in a Pch gate stack structure including a gate insulation film GIc including a lamination film of the oxide film 1s and the HfON film 3 (high dielectric constant film Hc), and the gate electrode GE1 or GE2 including a lamination film of the first metal film 11 (middle layer gate electrode 2M) and the second metal film 12 (top layer gate electrode 2U).

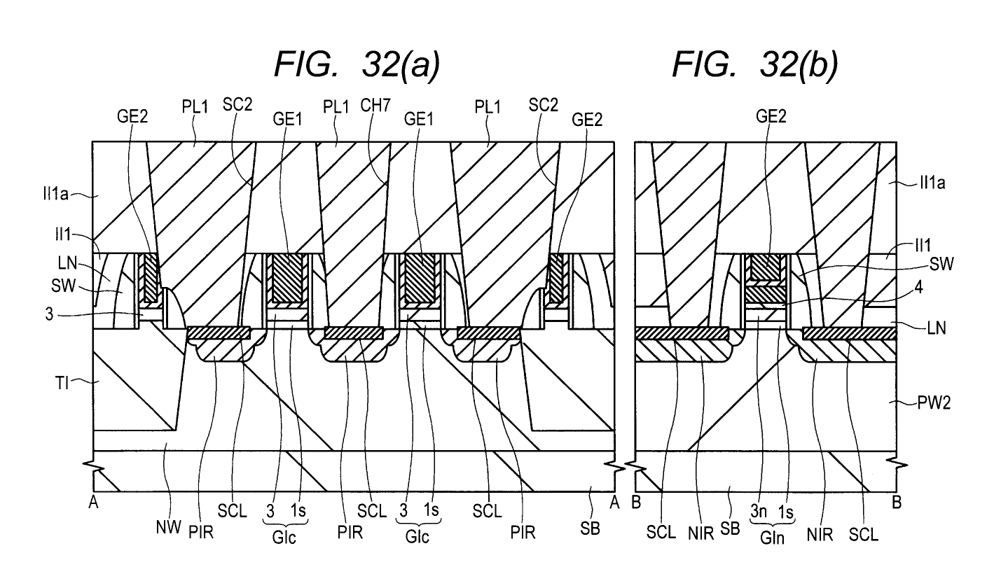

Then, as shown in FIGS. 32A and 32B, over the main surface of the semiconductor substrate SB, a second interlayer insulation film II1a is formed. Then, in the liner nitride film LN and the interlayer insulation films II1 and II1a, there are formed shared contact holes SC1 and SC2, contact holes CH1 to CH10, and the like using a photolithography method and a dry etching method.

Herein, the shared contact hole SC1 is formed so as to reach both of the gate electrode GE1 of the load transistor LT1 and the drain region PIR of the load transistor LT2 (so as to expose both surfaces). Whereas, the shared contact hole SC2 is formed so as to reach both of the gate electrode GE2 of the load transistor LT2 and the drain region PIR of the load transistor LT1 (so as to expose both surfaces).

Then, a conductive film including tungsten (W) is formed over the second interlayer insulation film II1a by, for example, a CVD method in such a manner as to fill the shared contact holes SC1 and SC2, the contact holes CH1 to CH10, and the like. Then, the conductive film is etched back until the surface of the second interlayer insulation film II1a is exposed. As a result, there are formed conductive films PL1 as contact plugs which fill the shared contact holes SC1 and SC2, the contact holes CH1 to CH10, and the like.

Then, formation of the insulation film and formation of the conductive film are repeated, thereby to manufacture the memory cell of the SRAM in accordance with the second embodiment shown in FIGS. 20 to 22.

Incidentally, in the present second embodiment, in each forming region of the transfer transistors AT1 and AT2 and the driving transistors DT1 and DT2 including nMISs, the cap film Cn containing La is formed, thereby to adjust the threshold voltages of the transfer transistors AT1 and AT2 and the driving transistors DT1 and DT2. The threshold voltages of the load transistors LT1 and LT2 including pMISs are adjusted by the first metal film 11 forming the gate electrodes GE1 and GE2. However, this configuration is not exclusive. For example, the following configuration can be adopted: in each forming region of the load transistors LT1 and LT2, a cap film containing Al is formed, thereby to adjust the threshold voltages of the load transistors LT1 and LT2. The threshold voltages of the transfer transistors AT1 and AT2 and the driving transistors DT1 and DT2 are adjusted by the metal film forming the gate electrodes GE1 and GE2.

Thus, in accordance with the present second embodiment, in addition to the effects of the first embodiment, it is possible to implement a further higher speed of the SRAM in addition to densification of the memory cell of the SRAM because respective gate electrodes of various transistors are formed of only metal materials.

Up to this point, the invention made by the present inventors was described specifically by way of embodiments. However, it is naturally understood that the present invention is not limited to the embodiments, and can be variously changed within the scope not departing from the gist thereof.

The present invention is applicable to a semiconductor device having shared contacts reaching both of the gate electrodes and the impurity regions.

What is claimed is:

1. A semiconductor device having at least one shared contact hole, comprising:
in a first region of a main surface of a semiconductor substrate, a first field effect transistor; a second field effect transistor; a first insulation film covering the first field effect transistor and the second field effect transistor; and a first shared contact hole formed in the first insulation film, and reaching both of a first gate electrode of the first field effect transistor and an impurity region forming a source/drain region of the second field effect transistor, and
in a second region different from the first region of the main surface of the semiconductor substrate, a third field effect transistor; a fourth field effect transistor; a second insulation film covering the third field effect transistor and the fourth field effect transistor; a second shared contact hole formed in the second insulation film, and reaching both of a third gate electrode of the third field effect transistor and an impurity region forming a source/drain region of the fourth field effect transistor,
wherein in the first region, the first gate electrode and a second gate electrode of the second field effect transistor are disposed in parallel with a predetermined distance interposed therebetween, the first gate electrode has a first near-side sidewall and a first far-side sidewall opposed to each other in plan view, and the first near-side sidewall of the first gate electrode at a portion thereof reached by the first shared contact hole, and the first near-side sidewall of the first gate electrode at a portion thereof located over a channel region are collinear in plan view,
wherein in the second region, the third gate electrode and a fourth gate electrode of the fourth field effect transistor are disposed in parallel with a predetermined distance interposed therebetween, the third gate electrode has a third near-side sidewall and a third far-side sidewall opposed to each other in plan view, and the third near-side sidewall of the third gate electrode at a portion thereof reached by the second shared contact hole is located to be displaced toward the third far-side sidewall from an imaginary extension of the third near-side sidewall of the third gate electrode at a portion thereof located over the channel region in plan view, and
wherein a first pitch between the first gate electrode and the second gate electrode in the first region is larger than a second pitch between the third gate electrode and the fourth gate electrode in the second region.

2. The semiconductor device according to claim 1,
wherein a first width along the gate length direction of a portion of the first gate electrode reached by the first shared contact hole is equal to a second width along the gate length direction of a portion of the first gate electrode located over the channel region, and
wherein a third width along the gate length direction of a portion of the third gate electrode reached by the second shared contact hole is smaller than a fourth width along the gate length direction of a portion of the third gate electrode located over the channel region.

3. The semiconductor device according to claim 2,
wherein the third width is shorter than the fourth width by 5 nm or more.

4. The semiconductor device according to claim 2,
wherein the third width is constant.

5. The semiconductor device according to claim 2,
wherein the first width, the second width, and the third width are equal to one another.

6. The semiconductor device according to claim 1,
wherein at respective opposite ends in their respective gate width directions of the first gate electrode, the second gate electrode, the third gate electrode, and the fourth gate electrode, the sidewalls thereof are formed in parallel along their respective gate length directions.

7. A semiconductor device having at least one shared contact hole, comprising:
an impurity region formed in a main surface of a semiconductor substrate;
a field effect transistor formed in the main surface, and including a pair of source/drain regions, and a gate electrode formed over a channel region interposed between the pair of source/drain regions via a gate insulation film;
an insulation film covering the impurity region and the field effect transistor; and
a shared contact hole reaching both of the gate electrode of the field effect transistor and the impurity region,
wherein the gate electrode has a near-side sidewall and a far-side sidewall opposed to each other in plan view,
wherein the gate electrode has a first portion which is reached by the shared contact hole and a second portion which is located over a channel region,
wherein the near-side sidewall at the first portion and the near-side sidewall at the second portion are non-collinear, and
wherein a width along the gate length direction of the portion of the gate electrode reached by the shared contact hole is shorter than a width along the gate length direction of the gate electrode over the channel region.

8. The semiconductor device according to claim 7,
wherein the width along the gate length direction of the first portion is shorter than the width along the gate length direction of the second portion by 5 nm or more.

9. The semiconductor device according to claim 7,
wherein the width along the gate length direction of the first portion is constant.

10. The semiconductor device according to claim 7,
wherein at the opposite ends in the gate width direction of the gate electrode, the sidewalls thereof are formed in parallel along the gate length direction.

11. A method for manufacturing a semiconductor device having at least one shared contact hole, comprising the steps of:
(a) respectively forming a first active region and a second active region surrounded by an element isolation part in a main surface of a semiconductor substrate;
(b) forming a first insulation film over respective surfaces of the first active region and the second active region, and then, forming a first conductor film over the main surface of the semiconductor substrate;
(c) applying a resist over the first conductor film, and then, performing first exposure on the resist using a first photomask having a plurality of first patterns each having a predetermined width, disposed at a predetermined pitch, and extending in a first direction, and second exposure on the resist using a second photomask having a plurality of tetragonal second patterns disposed in such a manner as to cut the first patterns at a plurality of sites;
(d) performing development on the resist, and forming a resist pattern;
(e) with the resist pattern as a mask, etching the first conductor film and the first insulation film, and thereby forming a gate electrode including the first conductor film having a channel region in the first active region;
(f) forming a sidewall at each sidewall of the gate electrode;
(g) introducing impurities into the second active region, and forming an impurity region;
(h) depositing a second insulation film over the main surface of the semiconductor substrate;
(i) forming a shared contact hole reaching both of the gate electrode and the impurity region in the second insulation film; and
(j) embedding a second conductor film in the inside of the shared contact hole,
wherein the gate electrode has a near-side sidewall and a far-side sidewall opposed to each other in plan view, and
wherein the gate electrode is formed such that the near-side sidewall of the gate electrode at a portion thereof reached by the shared contact hole is located to be displaced toward the far-side sidewall from an imaginary extension of the near-side sidewall of the gate electrode at a portion thereof located over the channel region in plan view.

12. The method for manufacturing a semiconductor device according to claim 11,
wherein a width along the gate length direction of the portion of the gate electrode reached by the shared contact hole is formed shorter than a width along the gate length direction of the gate electrode over the channel region.

13. A method for manufacturing a semiconductor device having at least one shared contact hole, comprising the steps of:
(a) respectively forming a first active region and a second active region surrounded by an element isolation part in a main surface of a semiconductor substrate;
(b) forming a first insulation film over the surface of the first active region, and then, forming a first conductor film over the main surface of the semiconductor substrate;
(c) applying a resist over the first conductor film, and then, performing first exposure on the resist using a first photomask having a plurality of first patterns each having a predetermined width, disposed at a predetermined pitch, and extending in a first direction, and second exposure on the resist using a second photomask having a plurality of tetragonal second patterns disposed in such a manner as to cut the first patterns at a plurality of sites;
(d) performing development on the resist, and forming a resist pattern;
(e) with the resist pattern as a mask, etching the first conductor film and the first insulation film, and thereby forming a dummy gate including the first conductor film having a channel region in the first active region;
(f) forming a sidewall at each sidewall of the dummy gate;
(g) introducing impurities into the second active region, and forming an impurity region;
(h) depositing a second insulation film over the main surface of the semiconductor substrate;
(i) polishing the second insulation film until the top surface of the first conductor film forming the dummy gate is exposed, and then, removing the first conductor film;
(j) depositing a metal film over the semiconductor substrate in such a manner as to fill a concave part from which the first conductor film has been removed;
(k) polishing the metal film, and forming a gate electrode including the metal film in the inside of the concave part;
(l) forming a third insulation film over the main surface of the semiconductor substrate;
(m) forming a shared contact hole reaching both of the gate electrode and the impurity region in the second insulation film and the third insulation film; and
(n) embedding a second conductor film in the inside of the shared contact hole,
wherein the gate electrode has a near-side sidewall and a far-side sidewall opposed to each other in plan view, and
wherein the gate electrode is formed such that the near-side sidewall of the gate electrode at a portion thereof reached by the shared contact hole is located to be displaced toward the far-side sidewall from an imaginary extension of the near-side sidewall of the gate electrode at a portion thereof located over the channel region in plan view.

14. The method for manufacturing a semiconductor device according to claim 13,
wherein a width along the gate length direction of the portion of the gate electrode reached by the shared contact hole is formed shorter than a width along the gate length direction of the gate electrode over the channel region.

15. A semiconductor device having at least one shared contact hole, comprising:
a first circuit comprising a first transistor having a first gate electrode and a second transistor having a second gate electrode, the first and second gate electrodes being separated by a first pitch;
a second circuit comprising a third transistor having a third gate electrode and a fourth transistor having a fourth gate electrode, the third and fourth gate electrodes being separated by a second pitch;
a first shared contact hole that is shared by the first gate electrode and an impurity source/drain region of the second transistor; and
a second shared contact hole that is shared by the third gate electrode and an impurity source/drain region of the fourth transistor;
wherein, in a plan view:
the first pitch is larger than the second pitch;
the third gate electrode has a notched portion having a notch formed therein; and
the second shared contact hole extends into the notch formed in the third gate electrode.

16. The semiconductor device according to claim 15, wherein:
a width of the third gate electrode at the notched portion is less than a width of the third gate electrode at a portion thereof that is not notched.

17. The semiconductor device according to claim 15, wherein:
the portion of the gate electrode that is not notched is formed over a channel region.

18. A semiconductor device having at least one shared contact hole in a memory cell circuit thereof, the semiconductor device comprising:
a first load transistor having a first gate electrode;
a second load transistor having a second gate electrode;
a first shared contact hole that is shared by the first gate electrode and an impurity source/drain region of the second load transistor; and
a second shared contact hole that is shared by the second gate electrode and an impurity source/drain region of the first load transistor;
wherein, in plan view:
the first gate electrode has a first notch formed therein and the first shared contact hole extends into the first notch; and
the second gate electrode has a second notch formed therein and the second shared contact hole extends into the second notch.

19. The semiconductor device according claim 18, wherein, in said plan view:
the first gate electrode has non-collinear first and second near-side sidewalls and collinear third and fourth far-side sidewalls;
the second gate electrode has non-collinear first and second near-side sidewalls and collinear third and fourth far-side sidewalls; and
the first and second near-side sidewalls of the first gate electrode, and the first and second near-side sidewalls of the second gate electrode, face toward each other.

20. The semiconductor device according claim 18, wherein, in said plan view:
the first gate electrode has non-collinear first and second near-side sidewalls and non-collinear third and fourth far-side sidewalls;
the second gate electrode has non-collinear first and second near-side sidewalls and non-collinear third and fourth far-side sidewalls; and
the first and second near-side sidewalls of the first gate electrode, and the first and second near-side sidewalls of the second gate electrode, face toward each other.

21. The semiconductor device according claim 18, wherein, in the memory cell circuit:
the first load transistor and a first driving transistor share the first gate electrode; and
a second load transistor and a second driving transistor share the second gate electrode.
